(19) United States
(12) Patent Application Publication
(10) Pub. No.: US 2026/0310080 A1
(43) Pub. Date: Oct. 8, 2026

(54) WET REMOVABLE SILICON-CONTAINING RESIST UNDERLAYER FILM-FORMING COMPOSITION

(71) Applicant: Nissan Chemical Corporation, Tokyo (JP)

(72) Inventors: Shuhei SHIGAKI, Toyama (JP); Wataru SHIBAYAMA, Toyama (JP)

(73) Assignee: Nissan Chemical Corporation, Tokyo (JP)

(21) Appl. No.: 19/478,602

(22) PCT Filed: Apr. 26, 2024
(86) PCT No.: PCT/JP2024/016416

§ 371 Date: Oct. 24, 2025

(30) Foreign Application Priority Data
Apr. 27, 2023 (JP) 2023-073388

(51) Int. Cl. G03F 7/11; H10P 76/20

(52) U.S. Cl. CPC G03F 7/11; H10P 76/2041

(57) ABSTRACT

A silicon-containing resist underlayer film-forming composition containing a hydrolysis condensate of a hydrolyzable silane mixture and an organic solvent, wherein
at least a part of silanol groups in the hydrolysis condensate is capped with an alcohol-based compound,
which is a composition for forming a silicon-containing resist underlayer film soluble in a basic chemical solution.

### TECHNICAL FIELD

The present invention relates to a silicon-containing resist underlayer film-forming composition, particularly to a wet removable silicon-containing resist underlayer film-forming composition.

### BACKGROUND ART

In the related art, microfabrication by lithography using photoresists has been performed in the production of semiconductor devices. The microfabrication is a processing method of forming microrelief corresponding to a pattern on a substrate surface by forming a thin film of a photoresist on a semiconductor substrate such as a silicon wafer, irradiating the thin film with an active ray such as an ultraviolet ray through a mask pattern on which a semiconductor device pattern is drawn, developing the thin film, and etching the substrate using the obtained photoresist pattern as a protective film.

In recent years, as a result of an increase in the degree of integration of semiconductor devices, active rays having a shorter wavelength have tended to be used, i.e. shifting from KrF excimer laser (248 nm) to ArF excimer laser (193 nm). With the shortening of the wavelength of an active ray, the influence of reflection of the active ray from the semiconductor substrate becomes a major problem, and a method for providing a resist underlayer film called an antireflection film (Bottom Anti-Reflective Coating, BARC) between a photoresist and a substrate to be processed has been widely applied.

A film known as a hard mask containing a metal element such as silicon or titanium has been used as an underlayer between a semiconductor substrate and a photoresist. In this case, the resist and the hard mask are significantly different in components, and the rates to remove the resist and hard mask by dry etching are greatly dependent on the types of gas used for dry etching. Therefore, the appropriate selection of a gas type allows the hard mask to be removed by dry etching without a large reduction in the film thickness of the photoresist. Thus, in the production of semiconductor devices in recent years, a resist underlayer film has been increasingly disposed between a semiconductor substrate and a photoresist to achieve various effects such as an antireflection effect.

Compositions for resist underlayer films have been studied so far. However, development of a new material for the resist underlayer film has been desired because a variety of characteristics are required for the resist underlayer film. For example, Patent Literature 1 discloses a coating-type composition for forming a boron phosphorus glass (BPSG) film containing a structure having a specific silicic acid as a skeleton in response to the issue of forming a wet-etchable film, and Patent Literature 2 discloses a silicon-containing resist underlayer film-forming composition containing a carbonyl structure in response to the issue of providing a method for removing a mask residue with a chemical solution after lithography.

### CITATION LIST

### Patent Literature

Patent Literature 1: JP 2016-74774 A
Patent Literature 2: WO 2018/181989 A

### SUMMARY OF INVENTION

### Technical Problem

In the most advanced semiconductor devices, while a multilayer process is frequently used due to miniaturization of an implant layer, transfer to an underlayer is usually performed by the above-described dry etching in the multilayer process, and finally processing of a substrate and removal of a mask residue after processing of the substrate, for example, a resist film or an underlayer film including a resist underlayer film, may also be performed by dry etching or ashing treatment. However, dry etching and ashing treatment do not cause little damage to the substrate, and improvement thereof is required.

The present invention has been made in view of the above circumstances, and an object of the present invention is to provide a silicon-containing resist underlayer film-forming composition capable of forming a resist underlayer film that can be peeled off not only by a conventional dry etching method but also by a wet etching method using a chemical solution such as dilute hydrofluoric acid, buffered hydrofluoric acid, or an alkaline chemical solution (basic chemical solution) in a processing step of a semiconductor substrate or the like, and can form a resist underlayer film exhibiting excellent solubility particularly in an alkaline chemical solution (basic chemical solution), a silicon-containing resist underlayer film that is formed from the silicon-containing resist underlayer film-forming composition, has excellent storage stability, and exhibits excellent solubility in a chemical solution, a laminate including the silicon-containing resist underlayer film, and a method for producing a semiconductor element using the silicon-containing resist underlayer film-forming composition, and a pattern method.

### Solution to Problem

As a result of intensive studies to solve the above problems, the present inventors have found that the above problems can be solved, and have completed the present invention having the following gist.

That is, the present invention includes the following aspects.

[1] A silicon-containing resist underlayer film-forming composition containing a hydrolysis condensate of a hydrolyzable silane mixture and an organic solvent, wherein
at least a part of silanol groups in the hydrolysis condensate is capped with an alcohol-based compound,
which is a composition for forming a silicon-containing resist underlayer film soluble in a basic chemical solution.

[2] The silicon-containing resist underlayer film-forming composition according to [1], wherein a cap ratio based on the alcohol-based compound in the hydrolysis condensate is 4% to 9%.

[3] The silicon-containing resist underlayer film-forming composition according to [1] or [2], wherein the alcohol-based compound is an alkylene glycol monoalkyl ether.

[4] The silicon-containing resist underlayer film-forming composition according to any one of [1] to [3], wherein the composition does not substantially contain water.

[5] The silicon-containing resist underlayer film-forming composition according to any one of [1] to [4], wherein the hydrolyzable silane mixture contains a hydrolyzable silane represented by the following Formula (1):

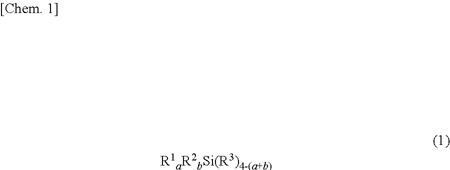

wherein,
R¹ is a group bonded to a silicon atom, and represents an organic group containing a succinic anhydride skeleton,
R² is a group bonded to a silicon atom, and each independently represents an optionally substituted alkyl group, an optionally substituted halogenated alkyl group, or an optionally substituted alkoxyalkyl group, or represents an organic group containing an epoxy group, an acryloyl group, a methacryloyl group, a mercapto group, an amino group, an amide group, an alkoxy group, a sulfonyl group, or a cyano group, or a combination thereof,
R³ is a group or atom bonded to a silicon atom, and each independently represents an alkoxy group, an aralkyloxy group, an acyloxy group, or a halogen atom,
a represents 1, b represents an integer of 0 to 2, and 4−(a+b) represents an integer of 1 to 3.

[6] The silicon-containing resist underlayer film-forming composition according to any one of [1] to [5], wherein the hydrolyzable silane mixture contains a hydrolyzable silane represented by the following Formula (2):

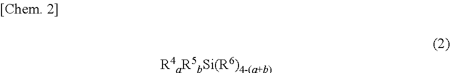

wherein,
R⁴ is a group bonded to a silicon atom, and substituted amino group,
R⁵ is a group bonded to a silicon atom, and each independently represents an optionally substituted alkyl group, an optionally substituted halogenated alkyl group, or an optionally substituted alkoxyalkyl group, or represents an organic group containing an epoxy group, an acryloyl group, a methacryloyl group, a mercapto group, an amino group, an amide group, an alkoxy group, a sulfonyl group, or a cyano group, or a combination thereof,
R⁶ is a group or atom bonded to a silicon atom, and each independently represents an alkoxy group, an aralkyloxy group, an acyloxy group, or a halogen atom, a represents 1, b represents an integer of 0 to 2, and 4−(a+b) represents an integer of 1 to 3.

[7] The silicon-containing resist underlayer film-forming composition according to any one of [1] to [6], wherein the hydrolyzable silane mixture contains a hydrolyzable silane represented by the following Formula (4):

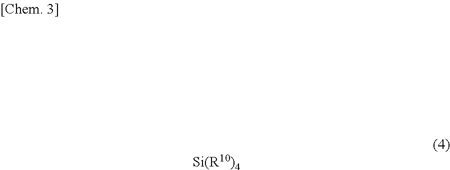

wherein
R¹⁰ is a group or atom bonded to a silicon atom, and each independently represents an alkoxy group, an aralkyloxy group, an acyloxy group, or a halogen atom.

[8] The silicon-containing resist underlayer film-forming composition according to [7], wherein a molar ratio of the hydrolyzable silane represented by Formula (4) in the hydrolyzable silane mixture is 50 mol % or more.

[9] The silicon-containing resist underlayer film-forming composition according to any one of [1] to [8], further containing a compound A having a chemical structure containing a cation AX⁺ and an anion AZ⁻, wherein the anion has a molecular weight of 65 or more.

[10] The silicon-containing resist underlayer film-forming composition according to [9], wherein the anion AZ⁻ is at least one anion selected from the group consisting of anions represented by the following (A) to (E):

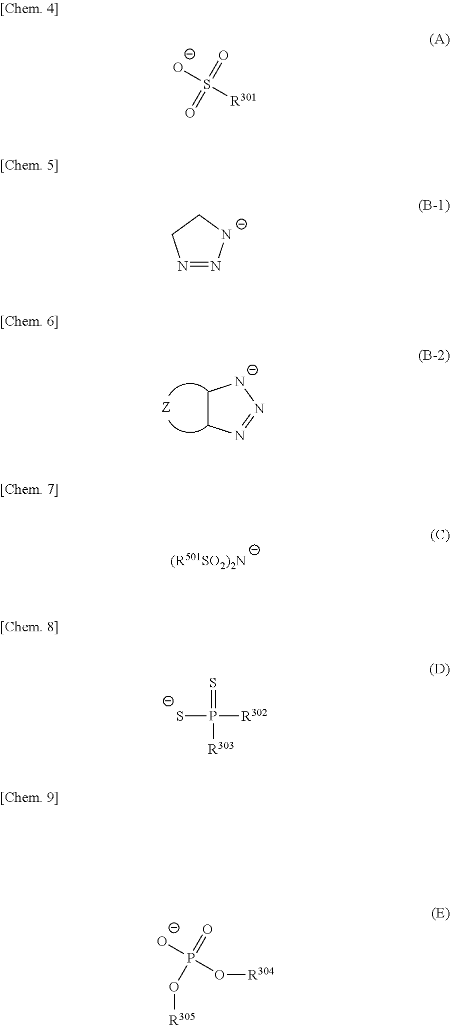

wherein in Formulae (A) to (E),
R³⁰¹ represents an optionally substituted alkyl group, an optionally substituted aryl group, an optionally substituted halogenated alkyl group, an optionally substituted aralkyl group, or an organic group containing an ester bond (—C(═O)—O— or —O—C(═O)—), or a combination thereof,
Z represents an aromatic ring, a cyclic alkane, or a cyclic alkene of a non-aromatic ring,
R⁵⁰¹ represents an alkyl group in which some or all may be substituted with a fluorine atom,
R³⁰² and R³⁰³ each independently represent an alkyl group, and
R³⁰⁴ and R³⁰⁵ each independently represent an alkyl group.

[11] The silicon-containing resist underlayer film-forming composition according to any one of [1] to [10], wherein the hydrolyzable silane mixture contains a hydrolyzable silane represented by the following Formula (3):

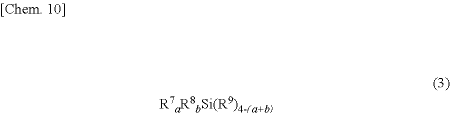

wherein,
R⁷ is a group bonded to a silicon atom, and represents an organic group containing an alkenyl group,
R⁸ is a group bonded to a silicon atom, and each independently represents an optionally substituted alkyl group, an optionally substituted halogenated alkyl group, or an optionally substituted alkoxyalkyl group, or represents an organic group containing an epoxy group, an acryloyl group, a methacryloyl group, a mercapto group, an amino group, an amide group, an alkoxy group, a sulfonyl group, or a cyano group, or a combination thereof,
R⁹ is a group or atom bonded to a silicon atom, and each independently represents an alkoxy group, an aralkyloxy group, an acyloxy group, or a halogen atom,
a represents 1, b represents an integer of 0 to 2, and 4−(a+b) represents an integer of 1 to 3.

[12] A silicon-containing resist underlayer film formed by using the resist underlayer film-forming composition according to any one of [1] to [11].

[13] A method for forming a pattern,
the method including steps of:
forming an organic underlayer film on a semiconductor substrate;
applying the resist underlayer film-forming composition according to any one of [1] to [11] on the organic underlayer film and baking to form a silicon-containing resist underlayer film;
forming a resist film on the silicon-containing resist underlayer film;
exposing and developing the resist film to obtain a resist pattern;
etching the silicon-containing resist underlayer film using the resist pattern as a mask; and
etching the organic underlayer film using the patterned silicon-containing resist underlayer film as a mask.

[14] The method for forming a pattern according to [13],
further including a step of removing the silicon-containing resist underlayer film by a wet method using a chemical solution, after the step of etching the organic underlayer film.

[15] The method for forming a pattern according to [14], wherein the chemical solution is a basic chemical solution.

### Advantageous Effects of Invention

According to the present invention, it is possible to provide a silicon-containing resist underlayer film-forming composition capable of forming a resist underlayer film that can be peeled off not only by a conventional dry etching method but also by a wet etching method using a chemical solution such as dilute hydrofluoric acid, buffered hydrofluoric acid, or an alkaline chemical solution (basic chemical solution) in a processing step of a semiconductor substrate or the like, and exhibits excellent solubility particularly in an alkaline chemical solution (basic chemical solution), a silicon-containing resist underlayer film that is formed from the silicon-containing resist underlayer film-forming composition, has excellent storage stability, and exhibits excellent solubility in a chemical solution, a laminate including the silicon-containing resist underlayer film, and a method for producing a semiconductor element using the silicon-containing resist underlayer film-forming composition, and a pattern method.

### DESCRIPTION OF EMBODIMENTS

Hereinafter, the present invention will be described in detail. Note that the description of the constituent requirements described below is an example for describing the present invention, and the present invention is not limited to the content thereof.

### [Silicon-Containing Resist Underlayer Film-Forming Composition]

The silicon-containing resist underlayer film-forming composition of the present invention is a composition for forming a silicon-containing resist underlayer film soluble in a basic chemical solution.

The silicon-containing resist underlayer film-forming composition contains a hydrolysis condensate and an organic solvent.

The hydrolysis condensate is a polysiloxane obtained by hydrolytically condensing a hydrolyzable silane mixture.

In the hydrolysis condensate, at least a part of silanol groups is capped with an alcohol-based compound.

In the hydrolysis condensate, since at least a part of silanol groups is capped with an alcohol-based compound, the silicon-containing resist underlayer film formed from the silicon-containing resist underlayer film-forming composition is soluble in a basic chemical solution, and can be peeled off even by the wet etching method. The present inventors consider that this is because when the silicon-containing resist underlayer film is formed from the silicon-containing resist underlayer film-forming composition, the condensation of the silanol group is moderately suppressed by the cap, and as a result, the crosslinking density of the film is moderately suppressed.

The number of carbon atoms of the alcohol-based compound is not particularly limited, but the number of carbon atoms is preferably 1 to 10, and more preferably 4 to 8.

The alcohol-based compound is not particularly limited as long as it has one OH group, and may be an alcohol (R¹—OH; R¹ represents an alkyl group.) or an alkylene glycol monoalkyl ether. Among them, alkylene glycol monoalkyl ethers are preferred.

Examples of the alkylene glycol monoalkyl ether include propylene glycol monomethyl ether (1-methoxy-2-propanol), propylene glycol monoethyl ether (1-ethoxy-2-propanol), propylene glycol monopropyl ether, propylene glycol monobutyl ether, ethylene glycol monomethyl ether, and ethylene glycol monoethyl ether. Among them, propylene glycol monoethyl ether (1-ethoxy-2-propanol) is preferred.

The state in which the alcohol-based compound caps the silanol group can be represented by, for example, the following formula:

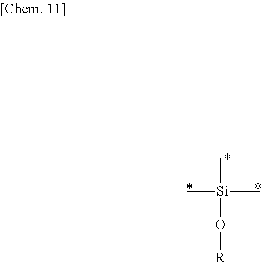

wherein R represents a residue obtained by removing an OH group from an alcohol-based compound, and * represents a bond.
R is preferably a —R^{a}OR^{b} group (R^{a} represents an alkylene group having 2 to 3 carbon atoms, and Rb represents an alkyl group having 1 to 4 carbon atoms).

The cap ratio based on the alcohol-based compound in the hydrolysis condensate is not particularly limited, but is preferably 2% to 15%, and more preferably 4% to 9% from the viewpoint of suitably obtaining the effect of the present invention.

Here, the cap ratio based on the alcohol-based compound can be determined as follows.

The cap ratio based on the alcohol-based compound is calculated by ¹HNMR. For the measurement, for example, JNM-ECA500 (manufactured by JEOL Ltd.) is used. As a heavy solvent, heavy acetone is used.

The integral ratio of the chemical shift value of the reference proton is taken as a reference.

The chemical shift value of the α-position methine proton of the secondary alcohol-based compound is detected around 3.8 ppm, but when a bond is formed with a silicon atom by a dehydration condensation reaction with a silanol group, that is, when a cap reaction occurs with respect to the silanol group, the chemical shift value of the methine proton moves to around 4.2 ppm. The integral ratio of the methine protons having moved to around 4.2 ppm is measured.

The cap ratio based on the alcohol-based compound is calculated by comparing with the integral ratio of the reference proton measured previously.

The cap ratio can be obtained by the following equation (Cap).

$$Cap ratio ( \% ) = [ A / ( B 1 / ( C \times D ) ) ] \times 100 \qquad Equation ( Cap )$$

A: Integral ratio of methine proton around 4.2 ppm
B: Integral ratio of reference proton
C: Number of reference protons in one molecule of hydrolyzable silane having reference proton
D: Molar ratio of hydrolyzable silane having reference proton to total hydrolyzable silane

For example, when the hydrolyzable silane mixture contains trialkoxymethylsilane, three protons of the methyl group bonded to the silicon atom of the trialkoxymethylsilane are preferentially used as the reference protons. When the hydrolyzable silane mixture contains trialkoxyphenylsilane, five protons of the phenyl group of the trialkoxyphenylsilane are used as the reference protons.

For example, when the hydrolysis condensate has 100 silicon atoms and silanol groups of 10 silicon atoms among the silicon atoms are capped, the cap ratio is 10%.

The capping of silanol groups by the alcohol-based compound is easily decapped by water. In other words, the alcohol-based compound capping the silanol group is easily desorbed from the silanol group by water. As a result, a silanol group appears.

Therefore, when the silicon-containing resist underlayer film-forming composition contains water, all of the silanol groups are likely to be uncapped by decapping. Then, the effect of the present invention is not obtained.

In this respect, it is preferable that the silicon-containing resist underlayer film-forming composition does not contain water as much as possible. Therefore, the content of water in the silicon-containing resist underlayer film-forming composition is preferably 5 mass % or less, more preferably 3 mass % or less, and particularly preferably a small amount, relative to the hydrolysis condensate. That is, it is particularly preferable that the silicon-containing resist underlayer film-forming composition does not substantially contain water.

However, in the hydrolysis condensation at the time of producing the hydrolysis condensate, water is used in order to perform hydrolysis. On the other hand, at the time of condensation, dehydration is performed in order to promote the reaction. However, the product containing the hydrolysis condensate may slightly contain water, which may be brought into the silicon-containing resist underlayer film-forming composition together with the hydrolysis condensate. In addition, other components to be blended in the silicon-containing resist underlayer film-forming composition (e.g. an organic solvent, a curing catalyst, a stabilizer, and the like) may coexist with water. In particular, a water-soluble organic solvent may contain water as an impurity in a commercially acceptable purity. In the present invention, such inevitable carrying of water into the silicon-containing resist underlayer film-forming composition is allowed. In the present invention, the phrase “does not substantially contain water” does not exclude inevitable carrying of water into the silicon-containing resist underlayer film-forming composition.

In the present invention, the hydrolysis condensate includes a polyorganosiloxane polymer which is a condensate prepared through complete condensation, and a polyorganosiloxane polymer which is a partial hydrolysis condensate prepared through incomplete condensation. Such a partial hydrolysis condensate is a polymer prepared through hydrolysis and condensation of a hydrolyzable silane compound, as in the case of a condensate prepared through complete condensation. However, the partial hydrolysis condensate contains remaining Si—OH groups, due to partial or incomplete hydrolysis and condensation of the silane compound. Further, the resist underlayer film-forming composition of the present invention may contain, besides the hydrolysis condensate, an uncondensed hydrolysate (complete hydrolysate or partial hydrolysate) or a remaining monomer (hydrolyzable silane compound). In the present specification, the “hydrolyzable silane” may be simply referred to as “silane compound”.

### <Hydrolysis Condensate of Hydrolyzable Silane Mixture>

The hydrolyzable silane mixture contains a plurality of hydrolyzable silanes.

The hydrolyzable silane mixture contains, for example, at least one of a hydrolyzable silane represented by the following Formula (1), a hydrolyzable silane represented by the following Formula (2), a hydrolyzable silane represented by the following Formula (3), a hydrolyzable silane represented by the following Formula (4), and a hydrolyzable silane represented by the following Formula (5).

The hydrolyzable silane mixture preferably contains a hydrolyzable silane represented by Formula (1).

The hydrolyzable silane mixture preferably contains a hydrolyzable silane represented by Formula (4).

The hydrolyzable silane mixture more preferably contains a hydrolyzable silane represented by Formula (1) and a hydrolyzable silane represented by Formula (4).

The hydrolyzable silane mixture may contain other hydrolyzable silanes.

The hydrolyzable silane mixture preferably contains a hydrolyzable silane represented by Formula (1) from the viewpoint of improving removability with an alkali chemical solution and improving the shape of a photoresist.

When the hydrolyzable silane mixture contains the hydrolyzable silane represented by Formula (4), the molar ratio of the hydrolyzable silane represented by Formula (4) in the hydrolyzable silane mixture is not particularly limited, but is preferably 50 mol % or more, and more preferably 60 mol % or more from the viewpoint of dry etching resistance. The molar ratio of the hydrolyzable silane represented by Formula (4) in the hydrolyzable silane mixture is preferably 90 mol % or less, more preferably 85 mol % or less, and particularly preferably 80 mol % or less from the viewpoint of removability with an alkali chemical solution.

Since the hydrolyzable silane represented by Formula (4) described later is a constituent element of a Q unit, when the hydrolyzable silane mixture contains a large amount of the hydrolyzable silane represented by Formula (4), the obtained silicon-containing resist underlayer film tends to have a high crosslinking density. Under such circumstances, in the hydrolysis condensate, when at least a part of silanol groups is capped with an alcohol-based compound, the crosslinking density of the film is moderately suppressed, and the silicon-containing resist underlayer film is easily dissolved in a basic chemical solution. In this regard, the present invention is particularly useful when the hydrolyzable silane mixture contains a hydrolyzable silane represented by Formula (4).

The hydrolyzable silane mixture more preferably contains a hydrolyzable silane represented by Formula (1) and a hydrolyzable silane represented by Formula (4).

### <<Silane Compound Represented by Formula (1) (Hydrolyzable Silane)>>

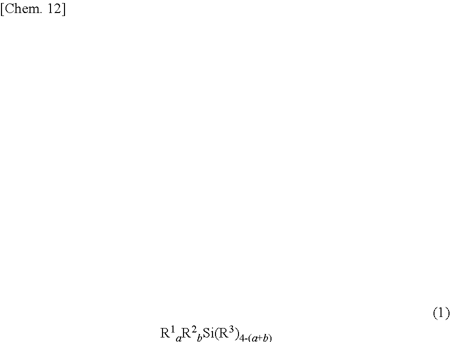

R¹ is a group bonded to a silicon atom, and represents an organic group containing a succinic anhydride skeleton.

R¹ is a group that does not hydrolyze. In other words, Si—R¹ is not dissociated by hydrolysis.

The organic group of R¹ is not particularly limited as long as the organic group contains the aforementioned skeleton.

Examples of the organic group containing a succinic anhydride skeleton include not only the skeleton itself but also an organic group in which one or more hydrogen atoms in an alkyl group are substituted with a succinic anhydride skeleton.

The alkyl group in which a hydrogen atom is substituted by the succinic anhydride skeleton or the like is not particularly limited, and may be linear, branched, or cyclic, and the number of carbon atoms thereof is ordinarily 40 or less, and may be, for example, 30 or less, 20 or less, or 10 or less.

Specific examples of the linear or branched alkyl group include, but are not limited to, a methyl group, an ethyl group, a n-propyl group, an i-propyl group, a n-butyl group, an i-butyl group, a s-butyl group, a t-butyl group, a n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, a n-hexyl group, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1-methyl-n-propyl group, and a 1-ethyl-2-methyl-n-propyl group.

Specific examples of the cyclic alkyl group include, but are not limited to, a cycloalkyl group (e.g., a cyclopropyl group, a cyclobutyl group, a 1-methyl-cyclopropyl group, a 2-methyl-cyclopropyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl, a 2-ethyl-3-methyl-cyclopropyl group) or a bicycloalkyl group (e.g., a bicyclobutyl group, a bicyclopentyl group, a bicyclohexyl group, a bicycloheptyl group, a bicyclooctyl group, a bicyclononyl group, a bicyclodecyl group).

Examples of the organic group of R¹ include a monovalent group represented by the following Formula (1-1).

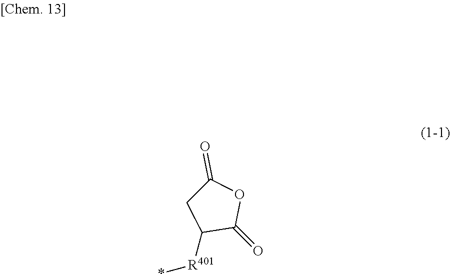

R⁴⁰¹ represents, for example, an alkylene group which is a divalent group derived by removing one hydrogen atom from the linear, branched, or cyclic alkyl group described above. * represents a bond bonded to a silicon atom.

In Formula (1), R² is a group bonded to a silicon atom, and each independently represents an optionally substituted alkyl group, an optionally substituted halogenated alkyl group, or an optionally substituted alkoxyalkyl group, or represents an organic group containing an epoxy group, an acryloyl group, a methacryloyl group, a mercapto group, an amino group, an amide group, an alkoxy group, a sulfonyl group, or a cyano group, or a combination thereof.

R² is a group that does not hydrolyze. In other words, Si—R² is not dissociated by hydrolysis.

Examples of the alkyl group in R² of Formula (1) include a linear or branched alkyl group having 1 to 10 carbon atoms, for example, a methyl group, an ethyl group, an n-propyl group, an i-propyl group, an n-butyl group, an i-butyl group, an s-butyl group, a t-butyl group, an n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, an n-hexyl group, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1-methyl-n-propyl group, and a 1-ethyl-2-methyl-n-propyl group.

Furthermore, a cyclic alkyl group can also be used, and examples of a cyclic alkyl group having 3 to 10 carbon atoms include a cyclopropyl group, a cyclobutyl group, a 1-methyl-cyclopropyl group, a 2-methyl-cyclopropyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl group, and a 2-ethyl-3-methyl-cyclopropyl group.

The halogenated alkyl group in R² of Formula (1) refers to an alkyl group substituted with a halogen atom.

Examples of the halogen atom include a fluorine atom, a chlorine atom, a bromine atom, and an iodine atom, and specific examples of the alkyl group include those described above.

The number of carbon atoms of the halogenated alkyl group is not particularly limited, but is preferably 40 or less, more preferably 30 or less, still more preferably 20 or less, and yet still more preferably 10 or less.

Specific examples of the halogenated alkyl group include, but are not limited to, a monofluoromethyl group, difluoromethyl group, trifluoromethyl group, bromodifluoromethyl group, 2-chloroethyl group, 2-bromoethyl group, 1,1-difluoroethyl group, 2,2,2-trifluoroethyl group, 1,1,2,2-tetrafluoroethyl group, 2-chloro-1,1,2-trifluoroethyl group, pentafluoroethyl group, 3-bromopropyl group, 2,2,3,3-tetrafluoropropyl group, 1,1,2,3,3,3-hexafluoropropyl group, 1,1,1,3,3,3-hexafluoropropan-2-yl group, 3-bromo-2-methylpropyl group, 4-bromobutyl group, and perfluoropentyl group.

The alkoxyalkyl group in R² of Formula (1) refers to an alkyl group substituted with an alkoxy group.

Specific examples of the alkyl group include those described above.

Specific examples of the alkoxy group include alkoxy groups having a linear, branched, or cyclic alkyl moiety having 1 to 20 carbon atoms. Examples of the linear or branched alkoxy group include a methoxy group, an ethoxy group, an n-propoxy group, an i-propoxy group, an n-butoxy group, an i-butoxy group, an s-butoxy group, a t-butoxy group, an n-pentyloxy group, a 1-methyl-n-butoxy group, a 2-methyl-n-butoxy group, a 3-methyl-n-butoxy group, a 1,1-dimethyl-n-propoxy group, a 1,2-dimethyl-n-propoxy group, a 2,2-dimethyl-n-propoxy group, a 1-ethyl-n-propoxy group, an n-hexyloxy group, a 1-methyl-n-pentyloxy group, a 2-methyl-n-pentyloxy group, a 3-methyl-n-pentyloxy group, a 4-methyl-n-pentyloxy group, a 1,1-dimethyl-n-butoxy group, a 1,2-dimethyl-n-butoxy group, a 1,3-dimethyl-n-butoxy group, a 2,2-dimethyl-n-butoxy group, a 2,3-dimethyl-n-butoxy group, a 3,3-dimethyl-n-butoxy group, a 1-ethyl-n-butoxy group, a 2-ethyl-n-butoxy group, a 1,1,2-trimethyl-n-propoxy group, a 1,2,2-trimethyl-n-propoxy group, a 1-ethyl-1-methyl-n-propoxy group, and a 1-ethyl-2-methyl-n-propoxy group.

Examples of the cyclic alkoxy group include, but are not limited thereto, a cyclopropoxy group, a cyclobutoxy group, a 1-methyl-cyclopropoxy group, a 2-methyl-cyclopropoxy group, a cyclopentyloxy group, a 1-methyl-cyclobutoxy group, a 2-methyl-cyclobutoxy group, a 3-methyl-cyclobutoxy group, a 1,2-dimethyl-cyclopropoxy group, a 2,3-dimethyl-cyclopropoxy group, a 1-ethyl-cyclopropoxy group, a 2-ethyl-cyclopropoxy group, a cyclohexyloxy group, a 1-methyl-cyclopentyloxy group, a 2-methyl-cyclopentyloxy group, a 3-methyl-cyclopentyloxy group, a 1-ethyl-cyclobutoxy group, a 2-ethyl-cyclobutoxy group, a 3-ethyl-cyclobutoxy group, a 1,2-dimethyl-cyclobutoxy group, a 1,3-dimethyl-cyclobutoxy group, a 2,2-dimethyl-cyclobutoxy group, a 2,3-dimethyl-cyclobutoxy group, a 2,4-dimethyl-cyclobutoxy group, a 3,3-dimethyl-cyclobutoxy group, a 1-n-propyl-cyclopropoxy group, a 2-n-propyl-cyclopropoxy group, a 1-i-propyl-cyclopropoxy group, a 2-i-propyl-cyclopropoxy group, a 1,2,2-trimethyl-cyclopropoxy group, a 1,2,3-trimethyl-cyclopropoxy group, a 2,2,3-trimethyl-cyclopropoxy group, a 1-ethyl-2-methyl-cyclopropoxy group, a 2-ethyl-1-methyl-cyclopropoxy group, a 2-ethyl-2-methyl-cyclopropoxy group, and a 2-ethyl-3-methyl-cyclopropoxy group.

The number of carbon atoms of the alkoxyalkyl group is not particularly limited, but is preferably 40 or less, more preferably 30 or less, still more preferably 20 or less, and yet still more preferably 10 or less.

Specific examples of the alkoxyalkyl group include, but are not limited to, lower alkyloxy lower alkyl groups, such as methoxymethyl group, ethoxymethyl group, 1-ethoxyethyl group, 2-ethoxyethyl group, and ethoxymethyl group.

Examples of the substituent in the alkyl group, halogenated alkyl group, or alkoxyalkyl group include an alkyl group, an aryl group, an aralkyl group, a halogenated alkyl group, a halogenated aryl group, a halogenated aralkyl group, an alkoxyalkyl group, an aryloxy group, an alkoxyaryl group, an alkoxyaralkyl group, an alkenyl group, an alkoxy group, and an aralkyloxy group. Among them, specific examples of the alkyl group, the halogenated alkyl group, the alkoxyalkyl group, and the alkoxy group, and the preferred number of carbon atoms thereof include those described above.

Examples of the aryl group described in the substituent include, but are not limited to, a phenyl group, an o-methylphenyl group, an m-methylphenyl group, a p-methylphenyl group, an o-chlorophenyl group, an m-chlorophenyl group, a p-chlorophenyl group, an o-fluorophenyl group, a p-mercaptophenyl group, an o-methoxyphenyl group, a p-methoxyphenyl group, a p-aminophenyl group, a p-cyanophenyl group, an α-naphthyl group, a β-naphthyl group, an o-biphenylyl group, an m-biphenylyl group, a p-biphenylyl group, a 1-anthryl group, a 2-anthryl group, a 9-anthryl group, a 1-phenanthryl group, a 2-phenanthryl group, a 3-phenanthryl group, a 4-phenanthryl group, and a 9-phenanthryl group.

Examples of the aralkyl group described in the substituent include, but are not limited to, a phenylmethyl group (benzyl group), a 2-phenylethylene group, a 3-phenyl-n-propyl group, a 4-phenyl-n-butyl group, a 5-phenyl-n-pentyl group, a 6-phenyl-n-hexyl group, a 7-phenyl-n-heptyl group, an 8-phenyl-n-octyl group, a 9-phenyl-n-nonyl group, and a 10-phenyl-n-decyl group.

The halogenated aryl group described in the substituent is an aryl group substituted with a halogen atom, and specific examples of the aryl group include those described above. Examples of the halogen atom include fluorine atom, chlorine atom, bromine atom, and iodine atom.

The number of carbon atoms of the halogenated aryl group is not particularly limited, but is preferably 40 or less, more preferably 30 or less, and still more preferably 20 or less.

Specific examples of the halogenated aryl group include a 2-fluorophenyl group, a 3-fluorophenyl group, a 4-fluorophenyl group, a 2,3-difluorophenyl group, a 2,4-difluorophenyl group, a 2,5-difluorophenyl group, a 2,6-difluorophenyl group, a 3,4-difluorophenyl group, a 3,5-difluorophenyl group, a 2,3,4-trifluorophenyl group, a 2,3,5-trifluorophenyl group, a 2,3,6-trifluorophenyl group, a 2,4,5-trifluorophenyl group, a 2,4,6-trifluorophenyl group, a 3,4,5-trifluorophenyl group, a 2,3,4,5-tetrafluorophenyl group, a 2,3,4,6-tetrafluorophenyl group, a 2,3,5,6-tetrafluorophenyl group, a pentafluorophenyl group, a 2-fluoro-1-naphthyl group, a 3-fluoro-1-naphthyl group, a 4-fluoro-1-naphthyl group, a 6-fluoro-1-naphthyl group, a 7-fluoro-1-naphthyl group, an 8-fluoro-1-naphthyl group, a 4,5-difluoro-1-naphthyl group, a 5,7-difluoro-1-naphthyl group, a 5,8-difluoro-1-naphthyl group, a 5,6,7,8-tetrafluoro-1-naphthyl group, a heptafluoro-1-naphthyl group, a 1-fluoro-2-naphthyl group, a 5-fluoro-2-naphthyl group, a 6-fluoro-2-naphthyl group, a 7-fluoro-2-naphthyl group, a 5,7-difluoro-2-naphthyl group, and a heptafluoro-2-naphthyl group, but not limited thereto.

The halogenated aralkyl group described in the substituent is an aralkyl group substituted with a halogen atom, and specific examples of the aralkyl group and the halogen atom include those described above.

The number of carbon atoms of the halogenated aralkyl group is not particularly limited, but is preferably 40 or less, more preferably 30 or less, and still more preferably 20 or less.

Specific examples of the halogenated aralkyl group include, but are not limited to, a 2-fluorobenzyl group, 3-fluorobenzyl group, 4-fluorobenzyl group, 2,3-difluorobenzyl group, 2,4-difluorobenzyl group, 2,5-difluorobenzyl group, 2,6-difluorobenzyl group, 3,4-difluorobenzyl group, 3,5-difluorobenzyl group, 2,3,4-trifluorobenzyl group, 2,3,5-trifluorobenzyl group, 2,3,6-trifluorobenzyl group, 2,4,5-trifluorobenzyl group, 2,4,6-trifluorobenzyl group, 2,3,4,5-tetrafluorobenzyl group, 2,3,4,6-tetrafluorobenzyl group, 2,3,5,6-tetrafluorobenzyl group, and 2,3,4,5,6-pentafluorobenzyl group.

The aryloxy group as described in the substituent is a group in which an aryl group is bonded via an oxygen atom (—O⁻), and specific examples of the aryl group include those described above. The number of carbon atoms of the aryloxy group is not particularly limited, but is preferably 40 or less, more preferably 30 or less, and still more preferably 20 or less, and specific examples thereof include a phenoxy group and a naphthalene-2-yloxy group, but are not limited thereto.

When two or more substituents are present, the substituents may be bonded together to form a ring.

The alkoxyaryl group described in the substituent is an aryl group substituted with an alkoxy group, and specific examples of the alkoxy group and the aryl group include those described above.

The number of carbon atoms of the alkoxyaryl group is not particularly limited, but is preferably 40 or less, more preferably 30 or less, and still more preferably 20 or less.

Specific examples of the alkoxyaryl group include, but are not limited to, a 2-methoxyphenyl group, 3-methoxyphenyl group, 4-methoxyphenyl group, 2-(1-ethoxy)phenyl group, 3-(1-ethoxy)phenyl group, 4-(1-ethoxy)phenyl group, 2-(2-ethoxy)phenyl group, 3-(2-ethoxy)phenyl group, 4-(2-ethoxy)phenyl group, 2-methoxynaphthalene-1-yl group, 3-methoxynaphthalene-1-yl group, 4-methoxynaphthalene-1-yl group, 5-methoxynaphthalene-1-yl group, 6-methoxynaphthalene-1-yl group, and 7-methoxynaphthalene-1-yl group.

The alkoxyaralkyl group described in the substituent is an aralkyl group substituted with an alkoxy group, and specific examples of the alkoxy group and the aralkyl group include those described above.

The number of carbon atoms of the alkoxyaralkyl group is not particularly limited, but is preferably 40 or less, more preferably 30 or less, and still more preferably 20 or less.

Specific examples of the alkoxyaralkyl group include, but are not limited to, a 3-(methoxyphenyl)benzyl group and a 4-(methoxyphenyl)benzyl group.

Examples of the alkenyl group described in the substituent include an optionally substituted alkenyl group, and examples thereof include an alkenyl group having 2 to 10 carbon atoms. More specific examples of the alkenyl group include an ethenyl group (vinyl group), 1-propenyl group, 2-propenyl group, 1-methyl-1-ethenyl group, 1-butenyl group, 2-butenyl group, 3-butenyl group, 2-methyl-1-propenyl group, 2-methyl-2-propenyl group, 1-ethylethenyl group, 1-methyl-1-propenyl group, 1-methyl-2-propenyl group, 1-pentenyl group, 2-pentenyl group, 3-pentenyl group, 4-pentenyl group, 1-n-propylethenyl group, 1-methyl-1-butenyl group, 1-methyl-2-butenyl group, 1-methyl-3-butenyl group, 2-ethyl-2-propenyl group, 2-methyl-1-butenyl group, 2-methyl-2-butenyl group, 2-methyl-3-butenyl group, 3-methyl-1-butenyl group, 3-methyl-2-butenyl group, 3-methyl-3-butenyl group, 1,1-dimethyl-2-propenyl group, 1-i-propylethenyl group, 1,2-dimethyl-1-propenyl group, 1,2-dimethyl-2-propenyl group, 1-cyclopentenyl group, 2-cyclopentenyl group, 3-cyclopentenyl group, 1-hexenyl group, 2-hexenyl group, 3-hexenyl group, 4-hexenyl group, 5-hexenyl group, 1-methyl-1-pentenyl group, 1-methyl-2-pentenyl group, 1-methyl-3-pentenyl group, 1-methyl-4-pentenyl group, 1-n-butylethenyl group, 2-methyl-1-pentenyl group, 2-methyl-2-pentenyl group, 2-methyl-3-pentenyl group, 2-methyl-4-pentenyl group, 2-n-propyl-2-propenyl group, 3-methyl-1-pentenyl group, 3-methyl-2-pentenyl group, 3-methyl-3-pentenyl group, 3-methyl-4-pentenyl group, 3-ethyl-3-butenyl group, 4-methyl-1-pentenyl group, 4-methyl-2-pentenyl group, 4-methyl-3-pentenyl group, 4-methyl-4-pentenyl group, 1,1-dimethyl-2-butenyl group, 1,1-dimethyl-3-butenyl group, 1,2-dimethyl-1-butenyl group, 1,2-dimethyl-2-butenyl group, 1,2-dimethyl-3-butenyl group, 1-methyl-2-ethyl-2-propenyl group, 1-s-butylethenyl group, 1,3-dimethyl-1-butenyl group, 1,3-dimethyl-2-butenyl group, 1,3-dimethyl-3-butenyl group, 1-i-butylethenyl group, 2,2-dimethyl-3-butenyl group, 2,3-dimethyl-1-butenyl group, 2,3-dimethyl-2-butenyl group, 2,3-dimethyl-3-butenyl group, 2-i-propyl-2-propenyl group, 3,3-dimethyl-1-butenyl group, 1-ethyl-1-butenyl group, 1-ethyl-2-butenyl group, 1-ethyl-3-butenyl group, 1-n-propyl-1-propenyl group, 1-n-propyl-2-propenyl group, 2-ethyl-1-butenyl group, 2-ethyl-2-butenyl group, 2-ethyl-3-butenyl group, 1,1,2-trimethyl-2-propenyl group, 1-t-butylethenyl group, 1-methyl-1-ethyl-2-propenyl group, 1-ethyl-2-methyl-1-propenyl group, 1-ethyl-2-methyl-2-propenyl group, 1-i-propyl-1-propenyl group, 1-i-propyl-2-propenyl group, 1-methyl-2-cyclopentenyl group, 1-methyl-3-cyclopentenyl group, 2-methyl-1-cyclopentenyl group, 2-methyl-2-cyclopentenyl group, 2-methyl-3-cyclopentenyl group, 2-methyl-4-cyclopentenyl group, 2-methyl-5-cyclopentenyl group, 2-methylene-cyclopentyl group, 3-methyl-1-cyclopentenyl group, 3-methyl-2-cyclopentenyl group, 3-methyl-3-cyclopentenyl group, 3-methyl-4-cyclopentenyl group, 3-methyl-5-cyclopentenyl group, 3-methylene-cyclopentyl group, 1-cyclohexenyl group, 2-cyclohexenyl group, and 3-cyclohexenyl group. Examples thereof also include crosslinked cyclic alkenyl groups such as a bicycloheptenyl group (norbornyl group).

The aralkyloxy group described in the substituent is a group derived by removing a hydrogen atom from a hydroxy group of aralkyl alcohol, and specific examples of the aralkyl group include those described above.

The number of carbon atoms of the aralkyloxy group is not particularly limited, but is preferably 40 or less, more preferably 30 or less, and still more preferably 20 or less.

Specific examples of the aralkyloxy group include, but are not limited to, a phenylmethyloxy group (benzyloxy group), 2-phenylethyleneoxy group, 3-phenyl-n-propyloxy group, 4-phenyl-n-butyloxy group, 5-phenyl-n-pentyloxy group, 6-phenyl-n-hexyloxy group, 7-phenyl-n-heptyloxy group, 8-phenyl-n-octyloxy group, 9-phenyl-n-nonyloxy group, and 10-phenyl-n-decyloxy group.

Examples of the organic group containing an epoxy group in R² of Formula (1) include, but are not limited to, a glycidoxymethyl group, a glycidoxyethyl group, a glycidoxypropyl group, a glycidoxybutyl group, and an epoxy cyclohexyl group.

Examples of the organic group containing an acryloyl group in R² of Formula (1) include, but are not limited to, an acryloylmethyl group, an acryloylethyl group, and an acryloylpropyl group.

Examples of the organic group containing a methacryloyl group in R² of Formula (1) include, but are not limited to, a methacryloylmethyl group, a methacryloylethyl group, and a methacryloylpropyl group.

Examples of the organic group containing a mercapto group in R² of Formula (1) include, but are not limited to, an ethylmercapto group, a butylmercapto group, a hexylmercapto group, and an octylmercapto group.

Examples of the organic group containing an amino group in R² of Formula (1) include, but are not limited to, an amino group, an aminomethyl group, an aminoethyl group, a dimethylaminoethyl group, and a dimethylaminopropyl group.

Examples of the organic group containing an alkoxy group in R² of Formula (1) include, but are not limited to, a methoxymethyl group and a methoxyethyl group. However, the organic group excludes a group wherein an alkoxy group is directly bonded to a silicon atom.

Examples of the organic group containing a sulfonyl group in R² of Formula (1) include, but are not limited to, a sulfonylalkyl group and a sulfonylaryl group.

Examples of the organic group containing a cyano group in R² of Formula (1) include, but are not limited to, a cyanoethyl group and a cyanopropyl group.

In Formula (1), R³ is a group or atom bonded to a silicon atom, and each independently represents an alkoxy group, an aralkyloxy group, an acyloxy group, or a halogen atom. Examples of the alkoxy group and the halogen atom include those described above.

The aralkyloxy group is a group derived by removing a hydrogen atom from a hydroxy group of aralkyl alcohol, and specific examples of the aralkyl group include those described above.

The number of carbon atoms of the aralkyloxy group is not particularly limited, but is preferably 40 or less, more preferably 30 or less, and still more preferably 20 or less.

Specific examples of the aralkyloxy group include, but are not limited to, a phenylmethyloxy group (benzyloxy group), 2-phenylethyleneoxy group, 3-phenyl-n-propyloxy group, 4-phenyl-n-butyloxy group, 5-phenyl-n-pentyloxy group, 6-phenyl-n-hexyloxy group, 7-phenyl-n-heptyloxy group, 8-phenyl-n-octyloxy group, 9-phenyl-n-nonyloxy group, and 10-phenyl-n-decyloxy group.

The acyloxy group is a group derived by removing a hydrogen atom from a carboxylic acid group of a carboxylic acid compound, and examples of the acyloxy group typically include, but are not limited to, an alkylcarbonyloxy group, an arylcarbonyloxy group, or an aralkylcarbonyloxy group, derived by removing a hydrogen atom from a carboxylic acid group of an alkyl carboxylic acid, an aryl carboxylic acid, or an aralkyl carboxylic acid. Specific examples of the alkyl group, aryl group, and aralkyl group in the alkyl carboxylic acid, aryl carboxylic acid, and aralkyl carboxylic acid include those described above.

Specific examples of the acyloxy group include an acyloxy group having 2 to 20 carbon atoms. Examples thereof include, but are not limited to, a methylcarbonyloxy group, ethylcarbonyloxy group, n-propylcarbonyloxy group, i-propylcarbonyloxy group, n-butylcarbonyloxy group, i-butylcarbonyloxy group, s-butylcarbonyloxy group, t-butylcarbonyloxy group, n-pentylcarbonyloxy group, 1-methyl-n-butylcarbonyloxy group, 2-methyl-n-butylcarbonyloxy group, 3-methyl-n-butylcarbonyloxy group, 1,1-dimethyl-n-propylcarbonyloxy group, 1,2-dimethyl-n-propylcarbonyloxy group, 2,2-dimethyl-n-propylcarbonyloxy group, 1-ethyl-n-propylcarbonyloxy group, n-hexylcarbonyloxy group, 1-methyl-n-pentylcarbonyloxy group, 2-methyl-n-pentylcarbonyloxy group, 3-methyl-n-pentylcarbonyloxy group, 4-methyl-n-pentylcarbonyloxy group, 1,1-dimethyl-n-butylcarbonyloxy group, 1,2-dimethyl-n-butylcarbonyloxy group, 1,3-dimethyl-n-butylcarbonyloxy group, 2,2-dimethyl-n-butylcarbonyloxy group, 2,3-dimethyl-n-butylcarbonyloxy group, 3,3-dimethyl-n-butylcarbonyloxy group, 1-ethyl-n-butylcarbonyloxy group, 2-ethyl-n-butylcarbonyloxy group, 1,1,2-trimethyl-n-propylcarbonyloxy group, 1,2,2-trimethyl-n-propylcarbonyloxy group, 1-ethyl-1-methyl-n-propylcarbonyloxy group, 1-ethyl-2-methyl-n-propylcarbonyloxy group, phenylcarbonyloxy group, and tosylcarbonyloxy group.

In Formula (1), a represents 1, b represents an integer of 0 to 2, and 4−(a+b) represents an integer of 1 to 3.
b preferably represents 0 or 1, and more preferably 0.

Specific examples of the compound represented by Formula (1) include silane compounds having a succinic anhydride skeleton such as [(3-trimethoxysilyl)propyl]succinic anhydride, [(3-triethoxysilyl)propyl]succinic anhydride, [(3-trimethoxysilyl)ethyl]succinic anhydride, and [(3-trimethoxysilyl)butyl]succinic anhydride.

The molar ratio of the hydrolyzable silane represented by Formula (1) in the hydrolyzable silane mixture is not particularly limited, but is preferably 0.1 mol % to 10 mol %, more preferably 0.3 mol % to 5 mol %, and particularly preferably 0.5 mol % to 3 mol %.

### <<Silane Compound Represented by Formula (2) (Hydrolyzable Silane)>>

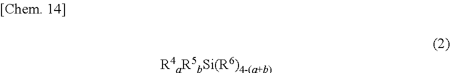

R⁴ is a group bonded to a silicon atom, and substituted amino group.

R⁴ is a group that does not hydrolyze. In other words, Si—R⁴ is not dissociated by hydrolysis.

Examples of the substituent in the optionally substituted amino group include an alkyl group having 1 to 4 carbon atoms and a phenyl group.

Examples of the optionally substituted amino group include a mono-substituted amino group and a di-substituted amino group in which an amino group (—NH₂), an alkyl group having 1 to 4 carbon atoms, or a phenyl group is substituted.

Examples of the organic group containing an optionally substituted amino group include an amino group, an aminomethyl group, an aminoethyl group, a dimethylaminoethyl group, a dimethylaminopropyl group, and a 3-phenylaminopropyl group.

In Formula (2), R⁵ is the same as R² in Formula (1).

In Formula (2), R⁶ is the same as R³ in Formula (1).

In Formula (2), a represents 1, b represents an integer of 0 to 2, and 4−(a+b) represents an integer of 1 to 3.

b preferably represents 0 or 1, and more preferably 0.

Specific examples of the compound represented by Formula (2) include dimethylaminopropyltrimethoxysilane, 3-phenylaminopropyltrimethoxysilane, and 3-phenylaminopropyltriethoxysilane.

The molar ratio of the hydrolyzable silane represented by Formula (2) in the hydrolyzable silane mixture is not particularly limited, but is preferably 0.01 mol % to 10 mol %, more preferably 0.03 mol % to 5 mol %, and particularly preferably 0.05 mol % to 3 mol %.

### <<Silane Compound Represented by Formula (3) (Hydrolyzable Silane)>>

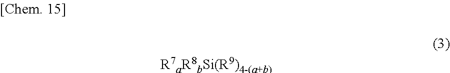

R⁷ is a group bonded to a silicon atom, and represents an organic group containing an alkenyl group. R⁷ is a group that does not hydrolyze. In other words, Si—R⁷ is not dissociated by hydrolysis.

The organic group of R⁷ is not particularly limited as long as the organic group contains an alkenyl group.

Examples of the organic group containing an alkenyl group include not only the alkenyl group itself but also an organic group in which one or more hydrogen atoms in an alkyl group are substituted with an alkenyl group.

Also, examples of the alkenyl group in R⁷ include an optionally substituted alkenyl group as described for R² in Formula (1), and examples thereof include an alkenyl group having 2 to 10 carbon atoms. More specific examples of the alkenyl group include an ethenyl group (vinyl group), 1-propenyl group, 2-propenyl group, 1-methyl-1-ethenyl group, 1-butenyl group, 2-butenyl group, 3-butenyl group, 2-methyl-1-propenyl group, 2-methyl-2-propenyl group, 1-ethylethenyl group, 1-methyl-1-propenyl group, 1-methyl-2-propenyl group, 1-pentenyl group, 2-pentenyl group, 3-pentenyl group, 4-pentenyl group, 1-n-propylethenyl group, 1-methyl-1-butenyl group, 1-methyl-2-butenyl group, 1-methyl-3-butenyl group, 2-ethyl-2-propenyl group, 2-methyl-1-butenyl group, 2-methyl-2-butenyl group, 2-methyl-3-butenyl group, 3-methyl-1-butenyl group, 3-methyl-2-butenyl group, 3-methyl-3-butenyl group, 1,1-dimethyl-2-propenyl group, 1-i-propylethenyl group, 1,2-dimethyl-1-propenyl group, 1,2-dimethyl-2-propenyl group, 1-cyclopentenyl group, 2-cyclopentenyl group, 3-cyclopentenyl group, 1-hexenyl group, 2-hexenyl group, 3-hexenyl group, 4-hexenyl group, 5-hexenyl group, 1-methyl-1-pentenyl group, 1-methyl-2-pentenyl group, 1-methyl-3-pentenyl group, 1-methyl-4-pentenyl group, 1-n-butylethenyl group, 2-methyl-1-pentenyl group, 2-methyl-2-pentenyl group, 2-methyl-3-pentenyl group, 2-methyl-4-pentenyl group, 2-n-propyl-2-propenyl group, 3-methyl-1-pentenyl group, 3-methyl-2-pentenyl group, 3-methyl-3-pentenyl group, 3-methyl-4-pentenyl group, 3-ethyl-3-butenyl group, 4-methyl-1-pentenyl group, 4-methyl-2-pentenyl group, 4-methyl-3-pentenyl group, 4-methyl-4-pentenyl group, 1,1-dimethyl-2-butenyl group, 1,1-dimethyl-3-butenyl group, 1,2-dimethyl-1-butenyl group, 1,2-dimethyl-2-butenyl group, 1,2-dimethyl-3-butenyl group, 1-methyl-2-ethyl-2-propenyl group, 1-s-butylethenyl group, 1,3-dimethyl-1-butenyl group, 1,3-dimethyl-2-butenyl group, 1,3-dimethyl-3-butenyl group, 1-i-butylethenyl group, 2,2-dimethyl-3-butenyl group, 2,3-dimethyl-1-butenyl group, 2,3-dimethyl-2-butenyl group, 2,3-dimethyl-3-butenyl group, 2-i-propyl-2-propenyl group, 3,3-dimethyl-1-butenyl group, 1-ethyl-1-butenyl group, 1-ethyl-2-butenyl group, 1-ethyl-3-butenyl group, 1-n-propyl-1-propenyl group, 1-n-propyl-2-propenyl group, 2-ethyl-1-butenyl group, 2-ethyl-2-butenyl group, 2-ethyl-3-butenyl group, 1,1,2-trimethyl-2-propenyl group, 1-t-butylethenyl group, 1-methyl-1-ethyl-2-propenyl group, 1-ethyl-2-methyl-1-propenyl group, 1-ethyl-2-methyl-2-propenyl group, 1-i-propyl-1-propenyl group, 1-i-propyl-2-propenyl group, 1-methyl-2-cyclopentenyl group, 1-methyl-3-cyclopentenyl group, 2-methyl-1-cyclopentenyl group, 2-methyl-2-cyclopentenyl group, 2-methyl-3-cyclopentenyl group, 2-methyl-4-cyclopentenyl group, 2-methyl-5-cyclopentenyl group, 2-methylene-cyclopentyl group, 3-methyl-1-cyclopentenyl group, 3-methyl-2-cyclopentenyl group, 3-methyl-3-cyclopentenyl group, 3-methyl-4-cyclopentenyl group, 3-methyl-5-cyclopentenyl group, 3-methylene-cyclopentyl group, 1-cyclohexenyl group, 2-cyclohexenyl group, and 3-cyclohexenyl group. Examples thereof also include crosslinked cyclic alkenyl groups such as a bicycloheptenyl group (norbornyl group).

Among the above, R⁷ is preferably a group containing a vinyl group.

In Formula (3), R⁸ is the same as R² in Formula (1).

In Formula (3), R⁹ is the same as R³ in Formula (1).

In Formula (3), a represents 1, b represents an integer of 0 to 2, and 4−(a+b) represents an integer of 1 to 3.

b preferably represents 0 or 1, and more preferably 0.

Specific examples of the compound represented by Formula (3) include silane compounds containing an alkenyl group (vinyl group) such as vinyltrimethoxysilane, vinyltriethoxysilane, vinyltrichlorosilane, vinyltriacetoxysilane, methylvinyldimethoxysilane, methylvinyldiethoxysilane, methylvinyldichlorosilane, methylvinyldiacetoxysilane, dimethylvinylmethoxysilane, dimethylvinylethoxysilane, dimethylvinylchlorosilane, dimethylvinylacetoxysilane, divinyldimethoxysilane, divinyldiethoxysilane, divinyldichlorosilane, divinyldiacetoxysilane, γ-glycidoxypropylvinyldimethoxysilane, γ-glycidoxypropylvinyldiethoxysilane, allyltrimethoxysilane, allyltriethoxysilane, allyltrichlorosilane, allyltriacetoxysilane, allylmethyldimethoxysilane, allylmethyldiethoxysilane, allylmethyldichlorosilane, allylmethyldiacetoxysilane, allyldimethylmethoxysilane, allyldimethylethoxysilane, allyldimethylchlorosilane, allyldimethylacetoxysilane, diallyldimethoxysilane, diallyldiethoxysilane, diallyldichlorosilane, diallyldiacetoxysilane, 3-allylaminopropyltrimethoxysilane, 3-allylaminopropyltriethoxysilane, and p-styryltrimethoxysilane.

The molar ratio of the hydrolyzable silane represented by Formula (3) in the hydrolyzable silane mixture is not particularly limited, but is preferably 30 mol % or less, more preferably 25 mol % or less, and particularly preferably 20 mol % or less. The lower limit of the molar ratio of the hydrolyzable silane represented by Formula (3) is, for example, 1 mol %, 3 mol %, or 5 mol %.

### <<Silane Compound Represented by Formula (4) (Hydrolyzable Silane)>>

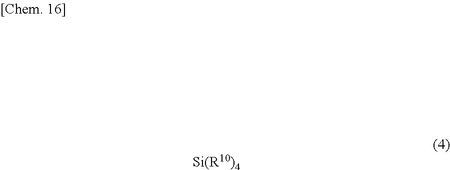

R¹⁰ is a group or atom bonded to a silicon atom, and each independently represents an alkoxy group, an aralkyloxy group, an acyloxy group, or a halogen atom.

Specific examples of the alkoxy group, aralkyloxy group, and acyloxy group include those described above.

Specific examples of the hydrolyzable silane represented by Formula (4) include tetramethoxysilane, tetrachlorosilane, tetraacetoxysilane, tetraethoxysilane, tetra-n-propoxysilane, tetra-i-propoxysilane, and tetra-n-butoxysilane.

It is preferable to use a tetrafunctional silane such as tetramethoxysilane or tetraethoxysilane represented by Formula (4) from the viewpoint of improving the crosslinking density of the film obtained from the composition of the present invention, suppressing diffusion of components of the resist film into the obtained film, and maintaining and improving the resist characteristics of the resist film.

### <<Silane Compound Represented by Formula (5) (Hydrolyzable Silane)>>

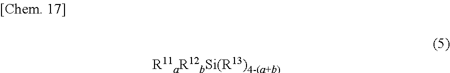

R¹¹ is a group bonded to a silicon atom, and represents an organic group containing at least one group selected from the group consisting of an aryl group and groups represented by Formula (5-2) described later.

R¹¹ is a group that does not hydrolyze. In other words, Si—R¹¹ is not dissociated by hydrolysis.

The organic group of R¹¹ is not particularly limited as long as the organic group contains the aforementioned group.

Examples of the organic group containing an aryl group and a group represented by Formula (5-2) described later include not only the group itself but also an organic group in which one or more hydrogen atoms in the alkyl group are substituted with at least one selected from the group consisting of an aryl group and groups represented by Formula (5-2) described later.

Examples of the aryl group in R¹¹ include an optionally substituted aryl group, and examples thereof include an aryl group having 6 to 20 carbon atoms. More specific examples of the aryl group include, as described for R² in Formula (1), a phenyl group, an o-methylphenyl group, an m-methylphenyl group, a p-methylphenyl group, an o-chlorophenyl group, an m-chlorophenyl group, a p-chlorophenyl group, an o-fluorophenyl group, a p-mercaptophenyl group, an o-methoxyphenyl group, a p-methoxyphenyl group, a p-aminophenyl group, a p-cyanophenyl group, an α-naphthyl group, a B-naphthyl group, an o-biphenylyl group, an m-biphenylyl group, a p-biphenylyl group, a 1-anthryl group, a 2-anthryl group, a 9-anthryl group, a 1-phenanthryl group, a 2-phenanthryl group, a 3-phenanthryl group, a 4-phenanthryl group, and a 9-phenanthryl group.

Further, examples of the group containing an aryl group include an optionally substituted aralkyl group, an optionally substituted halogenated aryl group, an optionally substituted halogenated aralkyl group, an optionally substituted alkoxyaryl group, and an optionally substituted alkoxyaralkyl group.

The aralkyl group is an alkyl group substituted with an aryl group, and specific examples of the aryl group and the alkyl group include those described above.

The number of carbon atoms of the aralkyl group is not particularly limited, but is preferably 40 or less, more preferably 30 or less, and still more preferably 20 or less.

Specific examples of the aralkyl group include, as described for R² in Formula (1), a phenylmethyl group (benzyl group), a 2-phenylethylene group, a 3-phenyl-n-propyl group, a 4-phenyl-n-butyl group, a 5-phenyl-n-pentyl group, a 6-phenyl-n-hexyl group, a 7-phenyl-n-heptyl group, an 8-phenyl-n-octyl group, a 9-phenyl-n-nonyl group, and a 10-phenyl-n-decyl group, but are not limited thereto.

The halogenated aryl group is an aryl group substituted with a halogen atom, and specific examples of the aryl group include those described above.

Examples of the halogen atom include a fluorine atom, a chlorine atom, a bromine atom, and an iodine atom. The number of carbon atoms of the halogenated aryl group is not particularly limited, but is preferably 40 or less, more preferably 30 or less, and still more preferably 20 or less.

Specific examples of the halogenated aryl group include, as described for R² in Formula (1), a 2-fluorophenyl group, a 3-fluorophenyl group, a 4-fluorophenyl group, a 2,3-difluorophenyl group, a 2,4-difluorophenyl group, a 2,5-difluorophenyl group, a 2,6-difluorophenyl group, a 3,4-difluorophenyl group, a 3,5-difluorophenyl group, a 2,3,4-trifluorophenyl group, a 2,3,5-trifluorophenyl group, a 2,3,6-trifluorophenyl group, a 2,4,5-trifluorophenyl group, a 2,4,6-trifluorophenyl group, a 3,4,5-trifluorophenyl group, a 2,3,4,5-tetrafluorophenyl group, a 2,3,4,6-tetrafluorophenyl group, a 2,3,5,6-tetrafluorophenyl group, a pentafluorophenyl group, a 2-fluoro-1-naphthyl group, a 3-fluoro-1-naphthyl group, a 4-fluoro-1-naphthyl group, a 6-fluoro-1-naphthyl group, a 7-fluoro-1-naphthyl group, an 8-fluoro-1-naphthyl group, a 4,5-difluoro-1-naphthyl group, a 5,7-difluoro-1-naphthyl group, a 5,8-difluoro-1-naphthyl group, a 5,6,7,8-tetrafluoro-1-naphthyl group, a heptafluoro-1-naphthyl group, a 1-fluoro-2-naphthyl group, a 5-fluoro-2-naphthyl group, a 6-fluoro-2-naphthyl group, a 7-fluoro-2-naphthyl group, a 5,7-difluoro-2-naphthyl group, and a heptafluoro-2-naphthyl group, but not limited thereto.

The halogenated aralkyl group is an aralkyl group substituted with a halogen atom, and specific examples of the aralkyl group and the halogen atom include those described above.

The number of carbon atoms of the halogenated aralkyl group is not particularly limited, but is preferably 40 or less, more preferably 30 or less, and still more preferably 20 or less.

Specific examples of the halogenated aralkyl group include, as described for R² in Formula (1), a 2-fluorobenzyl group, a 3-fluorobenzyl group, a 4-fluorobenzyl group, a 2,3-difluorobenzyl group, a 2,4-difluorobenzyl group, a 2,5-difluorobenzyl group, a 2,6-difluorobenzyl group, a 3,4-difluorobenzyl group, a 3,5-difluorobenzyl group, a 2,3,4-trifluorobenzyl group, a 2,3,5-trifluorobenzyl group, a 2,3,6-trifluorobenzyl group, a 2,4,5-trifluorobenzyl group, a 2,4,6-trifluorobenzyl group, a 2,3,4,5-tetrafluorobenzyl group, a 2,3,4,6-tetrafluorobenzyl group, a 2,3,5,6-tetrafluorobenzyl group, and a 2,3,4,5,6-pentafluorobenzyl group, but not limited thereto.

The alkoxyaryl group is an aryl group substituted with an alkoxy group, and specific examples of the aryl group and the alkoxy group include those described above.

The number of carbon atoms of the alkoxyaryl group is not particularly limited, but is preferably 40 or less, more preferably 30 or less, and still more preferably 20 or less.

Specific examples of the alkoxyaryl group include, as described for R² in Formula (1), a 2-methoxyphenyl group, a 3-methoxyphenyl group, a 4-methoxyphenyl group, a 2-(1-ethoxy)phenyl group, a 3-(1-ethoxy)phenyl group, a 4-(1-ethoxy)phenyl group, a 2-(2-ethoxy)phenyl group, a 3-(2-ethoxy)phenyl group, a 4-(2-ethoxy)phenyl group, a 2-methoxynaphthalene-1-yl group, a 3-methoxynaphthalene-1-yl group, a 4-methoxynaphthalene-1-yl group, a 5-methoxynaphthalene-1-yl group, a 6-methoxynaphthalene-1-yl group, and a 7-methoxynaphthalene-1-yl group, but are not limited thereto.

The alkoxyaralkyl group is an aralkyl group substituted with an alkoxy group, and specific examples of the alkoxy group and the aralkyl group include those described above.

The number of carbon atoms of the alkoxyaralkyl group is not particularly limited, but is preferably 40 or less, more preferably 30 or less, and still more preferably 20 or less.

Specific examples of the alkoxyaralkyl group include, but are not limited to, a 3-(methoxyphenyl)benzyl group and a 4-(methoxyphenyl)benzyl group.

In addition, examples of the group represented by the following Formula (5-2) in R¹¹ include:

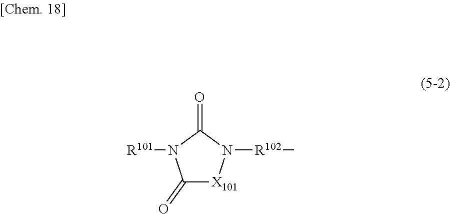

In Formula (5-2), each X₁₀₁ independently represents any one of the following Formulae (5-3) to (5-5), and a carbon atom of a ketone group in the following Formulae (5-4) and (5-5) is bonded to a nitrogen atom to which R¹⁰² in

Formula (5-2) is bonded.

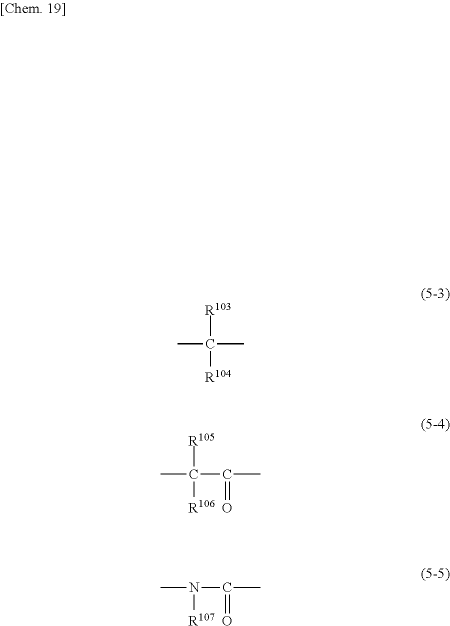

In Formulae (5-3) to (5-5), R¹⁰³ to R¹⁰⁷ each independently represent a hydrogen atom, an optionally substituted alkyl group, an optionally substituted alkenyl group, or an organic group containing an epoxy group or a sulfonyl group, and specific examples of the optionally substituted alkyl group and the optionally substituted alkenyl group, and suitable numbers of carbon atoms and the like include those described above as the alkyl group in which a hydrogen atom is substituted by a succinic anhydride skeleton or the like and those described above as the alkenyl group for R¹.

Also, examples of the organic group containing an epoxy group include, but are not limited to, a glycidoxymethyl group, a glycidoxyethyl group, a glycidoxypropyl group, a glycidoxybutyl group, and an epoxy cyclohexyl group.

Examples of the organic group containing a sulfonyl group include, but are not limited to, a sulfonylalkyl group and a sulfonylaryl group.

In Formula (5-2), each R¹⁰¹ independently represents a hydrogen atom, an optionally substituted alkyl group, an optionally substituted alkenyl group, or an organic group containing an epoxy group or a sulfonyl group, and each R¹⁰² independently represents an alkylene group, a hydroxyalkylene group, a sulfide bond (—S—), an ether bond (—O—), or an ester bond (—C(═O)—O— or —O—C(═O)—).

Here, specific examples of the optionally substituted alkyl group, the optionally substituted alkenyl group, and the organic group containing an epoxy group or an epoxy group, suitable numbers of carbon atoms and the like include those described above for R¹⁰³ to R¹⁰⁷. Besides these, the optionally substituted alkyl group is preferably an alkyl group in which a terminal hydrogen atom is substituted with a vinyl group, and specific examples thereof include an allyl group, a 2-vinylethyl group, a 3-vinylpropyl group, and a 4-vinylbutyl group.

The alkylene group is a divalent group derived by further removing one hydrogen atom from the alkyl group, and may be linear, branched, or cyclic, and the number of carbon atoms of the alkylene group is not particularly limited, but is preferably 40 or less, more preferably 30 or less, still more preferably 20 or less, and yet still more preferably 10 or less.

In addition, the alkylene group of R¹⁰² may have one or more types of bonds selected from a sulfide bond, an ether bond, and an ester bond at terminal ends or in the middle, and preferably in the middle.

Specific examples of the alkylene group include, but are not limited to, linear alkylene groups such as a methylene group, an ethylene group, a trimethylene group, a methylethylene group, a tetramethylene group, a pentamethylene group, a hexamethylene group, a heptamethylene group, an octamethylene group, a nonamethylene group and a decamethylene group; branched alkylene groups such as a 1-methyltrimethylene group, a 2-methyltrimethylene group, a 1,1-dimethylethylene group, a 1-methyltetramethylene group, a 2-methyltetramethylene group, a 1,1-dimethyltrimethylene group, a 1,2-dimethyltrimethylene group, a 2,2-dimethyltrimethylene group and a 1-ethyltrimethylene group; cyclic alkylene groups such as a 1,2-cyclopropanediyl group, 1,2-cyclobutanediyl, a 1,3-cyclobutanediyl group, 1,2-cyclohexanediyl and 1,3-cyclohexanediyl; and ether groups such as —CH₂OCH₂—, —CH₂CH₂OCH₂—, —CH₂CH₂OCH₂CH₂—, —CH₂CH₂CH₂OCH₂CH₂—, —CH₂CH₂OCH₂CH₂CH₂—, —CH₂CH₂CH₂OCH₂CH₂CH₂—, —CH₂SCH₂—, —CH₂CH₂SCH₂—, —CH₂CH₂SCH₂CH₂—, —CH₂CH₂CH₂SCH₂CH₂—, —CH₂CH₂SCH₂CH₂CH₂—, —CH₂CH₂CH₂SCH₂CH₂CH₂—, and —CH₂OCH₂CH₂SCH₂—.

The hydroxyalkylene group is a group in which at least one hydrogen atom of the alkylene group is replaced with a hydroxy group. Specific examples of the hydroxyalkylene group include, but are not limited to, a hydroxymethylene group, a 1-hydroxyethylene group, a 2-hydroxyethylene group, a 1,2-dihydroxyethylene group, a 1-hydroxytrimethylene group, a 2-hydroxytrimethylene group, a 3-hydroxytrimethylene group, a 1-hydroxytetramethylene group, a 2-hydroxytetramethylene group, a 3-hydroxytetramethylene group, a 4-hydroxytetramethylene group, a 1,2-dihydroxytetramethylene group, a 1,3-dihydroxytetramethylene group, a 1,4-dihydroxytetramethylene group, a 2,3-dihydroxytetramethylene group, a 2,4-dihydroxytetramethylene group, and a 4,4-dihydroxytetramethylene group.

Among the above, R¹¹ is preferably a group containing at least one selected from the group consisting of a phenyl group, a diaminopropyl group, and an isocyanuric acid skeleton (in Formula (5-2), X₁₀₁ represents a group represented by Formula (5-5)).

In Formula (5), R¹² is the same as R² in Formula (1).

In Formula (5), R¹³ is the same as R³ in Formula (1).

In Formula (5), a represents 1, b represents an integer of 0 to 2, and 4−(a+b) represents an integer of 1 to 3.

b preferably represents 0 or 1, and more preferably 0.

Specific examples of the compound represented by Formula (5) include silane compounds containing a phenyl group such as phenyltrimethoxysilane, phenyltriethoxysilane, phenyltrichlorosilane, phenyltriacetoxysilane, phenylmethyldimethoxysilane, phenylmethyldiethoxysilane, phenylmethyldichlorosilane, phenylmethyldiacetoxysilane, phenyldimethylmethoxysilane, phenyldimethylethoxysilane, phenyldimethylchlorosilane, phenyldimethylacetoxysilane, diphenylmethylmethoxysilane, diphenylmethylethoxysilane, diphenylmethylchlorosilane, diphenylmethylacetoxysilane, diphenyldimethoxysilane, diphenyldiethoxysilane, diphenyldichlorosilane, diphenyldiacetoxysilane, triphenylmethoxysilane, triphenylethoxysilane, triphenylacetoxysilane, triphenylchlorosilane, dimethoxymethyl-3-(3-phenoxypropylthiopropyl)silane, benzyltrimethoxysilane, benzyltriethoxysilane, benzylmethyldimethoxysilane, benzylmethyldiethoxysilane, benzyldimethylmethoxysilane, benzyldimethylethoxysilane, benzyldimethylchlorosilane, phenethyltrimethoxysilane, phenethyltriethoxysilane, phenethyltrichlorosilane, phenethyltriacetoxysilane, phenethylmethyldimethoxysilane, phenethylmethyldiethoxysilane, phenethylmethyldichlorosilane, and phenethylmethyldiacetoxysilane; and silane compounds containing a substituted aryl group such as methoxyphenyltrimethoxysilane, methoxyphenyltriethoxysilane, methoxyphenyltriacetoxysilane, methoxyphenyltrichlorosilane, methoxybenzyltrimethoxysilane, methoxybenzyltriethoxysilane, methoxybenzyltriacetoxysilane, methoxybenzyltrichlorosilane, methoxyphenethyltrimethoxysilane, methoxyphenethyltriethoxysilane, methoxyphenethyltriacetoxysilane, methoxyphenethyltrichlorosilane, ethoxyphenyltrimethoxysilane, ethoxyphenyltriethoxysilane, ethoxyphenyltriacetoxysilane, ethoxyphenyltrichlorosilane, ethoxybenzyltrimethoxysilane, ethoxybenzyltriethoxysilane, ethoxybenzyltriacetoxysilane, ethoxybenzyltrichlorosilane, i-propoxyphenyltrimethoxysilane, i-propoxyphenyltriethoxysilane, i-propoxyphenyltriacetoxysilane, i-propoxyphenyltrichlorosilane, i-propoxybenzyltrimethoxysilane, i-propoxybenzyltriethoxysilane, i-propoxybenzyltriacetoxysilane, i-propoxybenzyltrichlorosilane, t-butoxyphenyltrimethoxysilane, t-butoxyphenyltriethoxysilane, t-butoxyphenyltriacetoxysilane, t-butoxyphenyltrichlorosilane, t-butoxybenzyltrimethoxysilane, t-butoxybenzyltriethoxysilane, t-butoxybenzyltriacetoxysilane, t-butoxybenzyltrichlorosilane, methoxynaphthyltrimethoxysilane, methoxynaphthyltriethoxysilane, methoxynaphthyltriacetoxysilane, methoxynaphthyltrichlorosilane, ethoxynaphthyltrimethoxysilane, ethoxynaphthyltriethoxysilane, ethoxynaphthyltriacetoxysilane, and ethoxynaphthyltrichlorosilane.

Further, as a specific example of the silane compound represented by Formula (5), a commercially available product may be used as the silane compound in which R¹¹ in the formula is an organic group containing a group represented by Formula (5-2), and the silane compound can be also synthesized by a known method described in WO 2011/102470 A and the like.

Specific examples of the silane compound containing an organic group containing a group represented by Formula (5-2) include, but are not limited to, the following compounds.

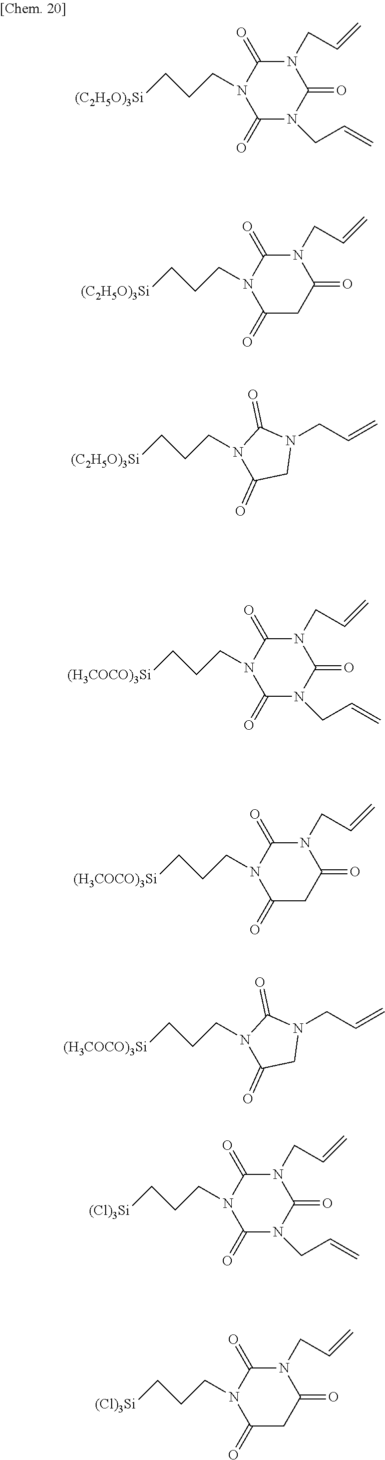

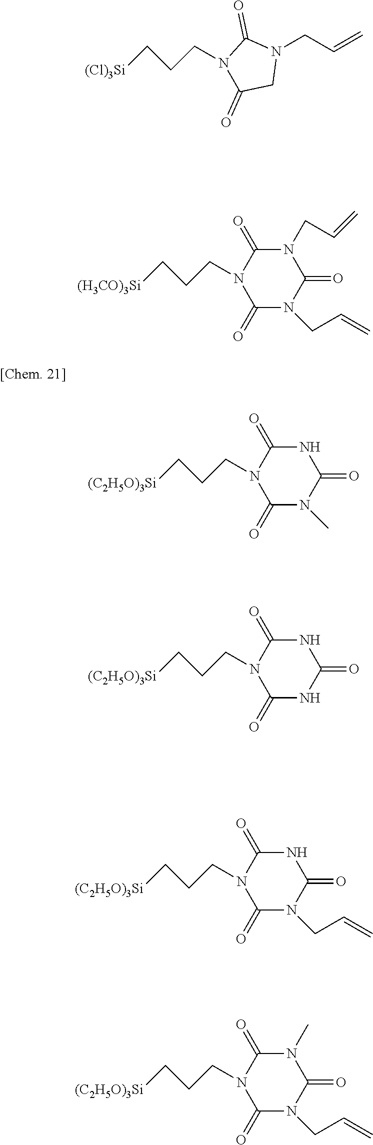

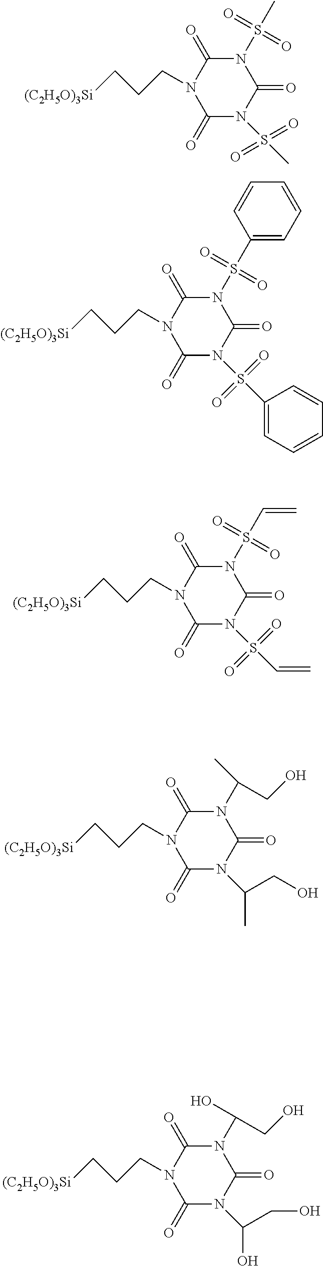

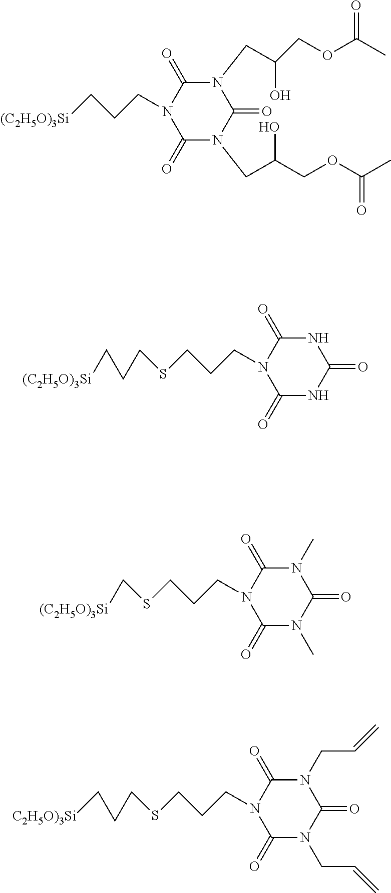

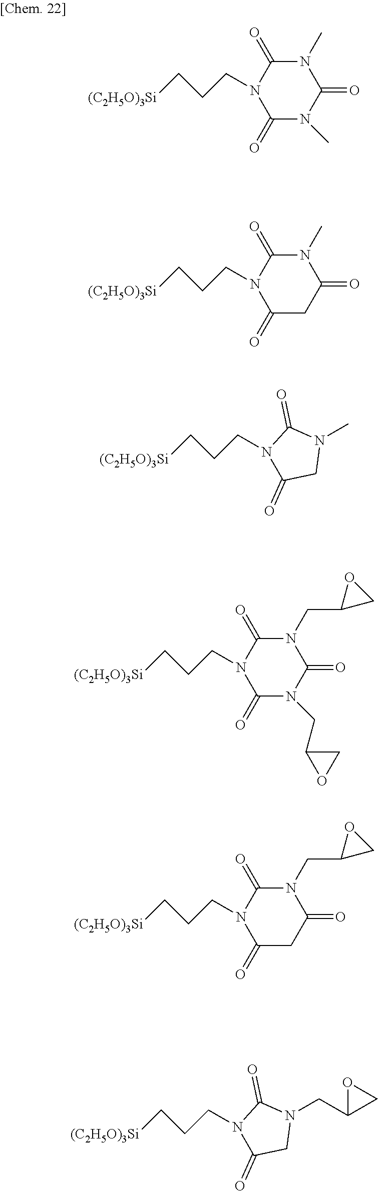

Furthermore, examples of the silane compound represented by Formula (5) include aryl group-containing silane compounds represented by Formulae (A-1) to (A-41).

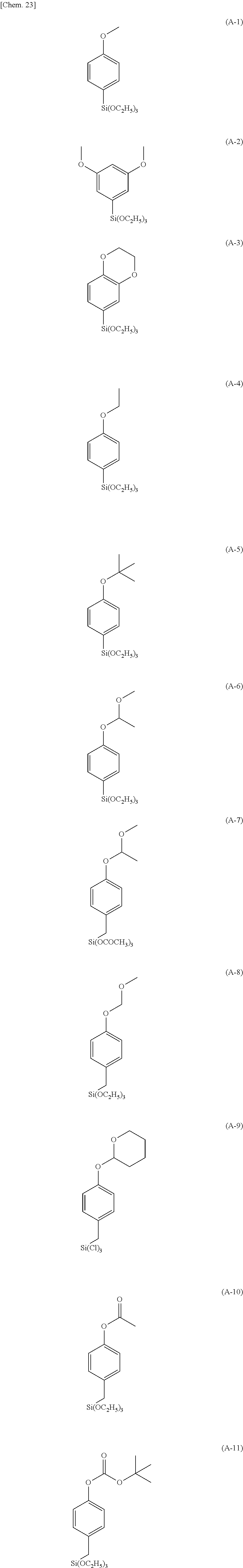

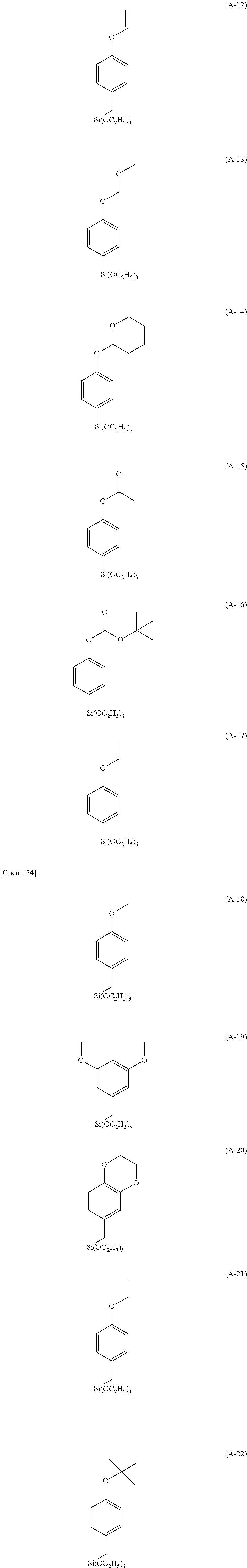

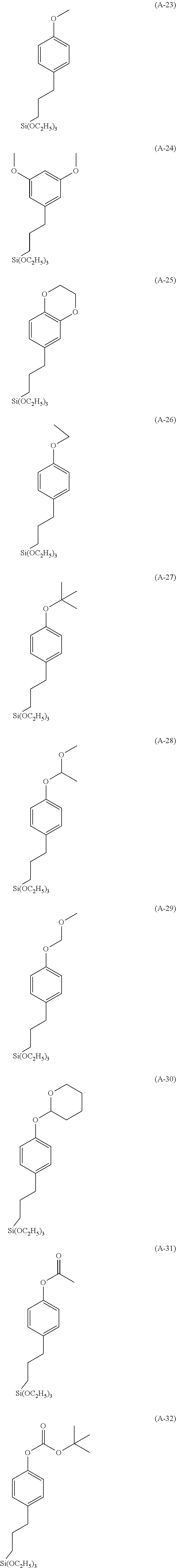

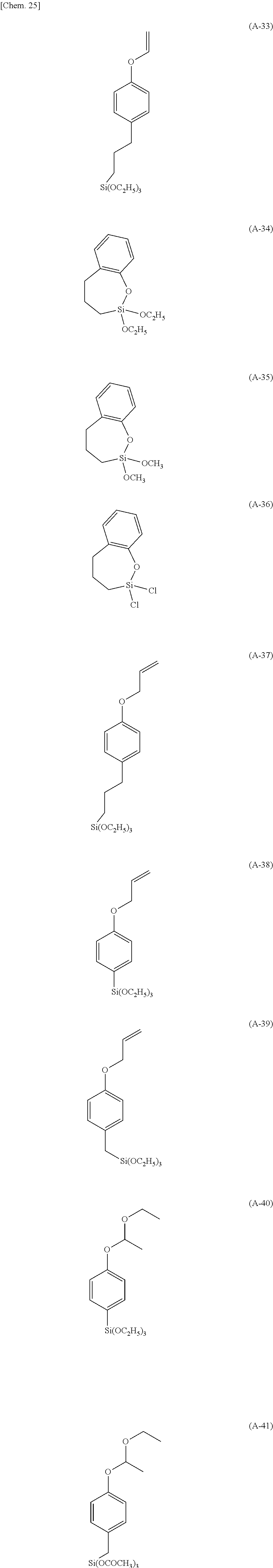

The molar ratio of the hydrolyzable silane represented by Formula (5) in the hydrolyzable silane mixture is not particularly limited, but is preferably 5 mol % to 35 mol %, more preferably 7 mol % to 30 mol %, and particularly preferably 10 mol % to 25 mol %.

### <<Other Silane Compounds (Hydrolyzable Silanes)>>

In the present invention, for the purpose of adjusting film physical properties such as film density, other silane compounds represented by the following Formula (6) (other hydrolyzable silanes) can be used in the hydrolyzable silane mixture together with at least one of the hydrolyzable silanes represented by Formulae (1) to (5). The hydrolyzable silane represented by Formula (6) is a compound other than the hydrolyzable silanes represented by Formulae (1) to (5).

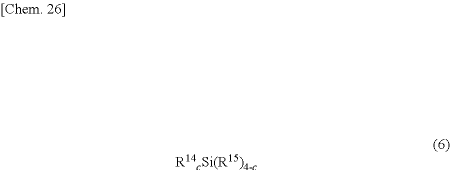

In Formula (6), R¹⁴ is a group bonded to a silicon atom, and each independently represents an optionally substituted alkyl group, an optionally substituted halogenated alkyl group, or an optionally substituted alkoxyalkyl group, or represents an organic group containing an epoxy group, an acryloyl group, a methacryloyl group, a mercapto group, an amide group, an alkoxy group, a sulfonyl group, or a cyano group, or a combination thereof.

R¹⁵ is a group or atom bonded to a silicon atom, and each independently represents an alkoxy group, an aralkyloxy group, an acyloxy group, or a halogen atom.

c represents an integer of 1 to 3.

Specific examples of each group in R¹⁴ and the suitable number of carbon atoms thereof may include the groups and the number of carbon atoms described above for R² in Formula (1).

Specific examples of each group in R¹⁵ and the suitable number of carbon atoms thereof may include the groups and atoms and the number of carbon atoms described above for R³ in Formula (1).

Specific examples of the hydrolyzable silane represented by Formula (6) include, but are not limited to, methyltrimethoxysilane, methyltrichlorosilane, methyltriacetoxysilane, methyltriethoxysilane, methyltripropoxysilane, methyltributoxysilane, methyltriamyloxysilane, methyltribenzyloxysilane, methyltriphenethyloxysilane, glycidoxymethyltrimethoxysilane, glycidoxymethyltriethoxysilane, α-glycidoxyethyltrimethoxysilane, α-glycidoxyethyltriethoxysilane, β-glycidoxyethyltrimethoxysilane, β-glycidoxyethyltriethoxysilane, α-glycidoxypropyltrimethoxysilane, α-glycidoxypropyltriethoxysilane, β-glycidoxypropyltrimethoxysilane, β-glycidoxypropyltriethoxysilane, γ-glycidoxypropyltrimethoxysilane, γ-glycidoxypropyltriethoxysilane, γ-glycidoxypropyltripropoxysilane, γ-glycidoxypropyltributoxysilane, α-glycidoxybutyltrimethoxysilane, α-glycidoxybutyltriethoxysilane, β-glycidoxybutyltriethoxysilane, γ-glycidoxybutyltrimethoxysilane, γ-glycidoxybutyltriethoxysilane, δ-glycidoxybutyltrimethoxysilane, δ-glycidoxybutyltriethoxysilane, (3,4-epoxycyclohexyl)methyltrimethoxysilane, (3,4-epoxycyclohexyl)methyltriethoxysilane, β-(3,4-epoxycyclohexyl)ethyltrimethoxysilane, β-(3,4-epoxycyclohexyl)ethyltriethoxysilane, β-(3,4-epoxycyclohexyl)ethyltripropoxysilane, β-(3,4-epoxycyclohexyl)ethyltributoxysilane, γ-(3,4-epoxycyclohexyl)propyltrimethoxysilane, γ-(3,4-epoxycyclohexyl)propyltriethoxysilane, δ-(3,4-epoxycyclohexyl)butyltrimethoxysilane, δ-(3,4-epoxycyclohexyl)butyltriethoxysilane, glycidoxymethylmethyldimethoxysilane, glycidoxymethylmethyldiethoxysilane, α-glycidoxyethylmethyldimethoxysilane, α-glycidoxyethylmethyldiethoxysilane, β-glycidoxyethylmethyldimethoxysilane, β-glycidoxyethylethyldimethoxysilane, α-glycidoxypropylmethyldimethoxysilane, α-glycidoxypropylmethyldiethoxysilane, β-glycidoxypropylmethyldimethoxysilane, β-glycidoxypropylethyldimethoxysilane, γ-glycidoxypropylmethyldimethoxysilane, γ-glycidoxypropylmethyldipropoxysilane, γ-glycidoxypropylmethyldibutoxysilane, γ-glycidoxypropylethyldimethoxysilane, γ-glycidoxypropylethyldiethoxysilane, ethyltrimethoxysilane, ethyltriethoxysilane, γ-chloropropyltrimethoxysilane, γ-chloropropyltriethoxysilane, γ-chloropropyltriacetoxysilane, 3,3,3-trifluoropropyltrimethoxysilane, γ-methacryloxypropyltrimethoxysilane, γ-mercaptopropyltrimethoxysilane, γ-mercaptopropyltriethoxysilane, β-cyanoethyltriethoxysilane, chloromethyltrimethoxysilane, chloromethyltriethoxysilane, bicyclo(2,2,1)heptenyltriethoxysilane, benzenesulfonylpropyltriethoxysilane, benzenesulfonamidopropyltriethoxysilane, dimethyldimethoxysilane, dimethyldiethoxysilane, γ-chloropropylmethyldimethoxysilane, γ-chloropropylmethyldiethoxysilane, dimethyldiacetoxysilane, y-methacryloxypropylmethyldimethoxysilane, γ-methacryloxypropylmethyldiethoxysilane, γ-mercaptopropylmethyldimethoxysilane, and γ-mercaptomethyldiethoxysilane.

In addition to the above examples, the hydrolyzable silane mixture may contain other silane compounds (hydrolyzable silanes) other than the above examples as long as the effect of the present invention is not impaired.

The hydrolysis condensate of the hydrolyzable silane mixture may have a weight-average molecular weight of, for example, 500 to 1,000,000. From the viewpoint of preventing the precipitation of the hydrolysis condensate in the composition, the weight-average molecular weight is preferably 500,000 or less, more preferably 250,000 or less, and still more preferably 100,000 or less. From the viewpoint of the compatibility between storage stability and application property, the weight-average molecular weight may be preferably 700 or more, more preferably 1,000 or more.

The weight-average molecular weight is determined by GPC analysis in terms of polystyrene. The GPC analysis can be performed under the following conditions: GPC apparatus (trade name: HLC-8220GPC, manufactured by Tosoh Corporation), GPC columns (trade name: Shodex (registered trademark) KF803L, KF802, and KF801, manufactured by Showa Denko K.K.), column temperature of 40° C., tetrahydrofuran as an eluent (elution solvent), flow amount (flow rate) of 1.0 mL/min, and polystyrene (manufactured by Showa Denko K. K.) as a standard sample.

The hydrolysis condensate of the hydrolyzable silane mixture is prepared by hydrolysis and condensation of the above-described silane compound (hydrolyzable silane).

The silane compound (hydrolyzable silane) contains an alkoxy group, aralkyloxy group, acyloxy group, or halogen atom directly bonded to a silicon atom; i.e. an alkoxysilyl group, an aralkyloxysilyl group, an acyloxysilyl group, or a halogenated silyl group, that is a hydrolyzable group.

For the hydrolysis of the hydrolyzable group, ordinarily 0.5 to 100 mol, preferably 1 to 10 mol, of water is used per mol of the hydrolyzable group.

During hydrolysis and condensation, a hydrolysis catalyst may be used for the purpose of promoting the reaction. Alternatively, the hydrolysis and condensation may be performed without use of a hydrolysis catalyst. When a hydrolysis catalyst is used, the amount of the hydrolysis catalyst is ordinarily 0.0001 to 10 mol, preferably 0.001 to 1 mol per mol of the hydrolyzable group.

The reaction temperature for the hydrolysis and condensation is ordinarily equal to or higher than room temperature, and equal to or lower than the reflux temperature at normal pressure of an organic solvent usable for hydrolysis. The reaction temperature may be, for example, 20 to 110° C., or, for example, 20 to 80° C.

The hydrolysis may be performed completely; i.e. all hydrolyzable groups may be converted into silanol groups, or may be performed partially; i.e. unreacted hydrolyzable groups may remain.

Examples of the hydrolysis catalyst usable for the hydrolysis and condensation include a metal chelate compound, an organic acid, an inorganic acid, an organic base, and an inorganic base.

Examples of the metal chelate compound as the hydrolysis catalyst include, but are not limited to, titanium chelate compounds such as triethoxy-mono(acetylacetonate)titanium, tri-n-propoxy-mono(acetylacetonate)titanium, tri-i-propoxy-mono(acetylacetonate)titanium, tri-n-butoxy-mono(acetylacetonate)titanium, tri-sec-butoxy-mono(acetylacetonate)titanium, tri-t-butoxy-mono(acetylacetonate)titanium, diethoxy-bis(acetylacetonate)titanium, di-n-propoxy-bis(acetylacetonate)titanium, di-i-propoxy-bis(acetylacetonate)titanium, di-n-butoxy-bis(acetylacetonate)titanium, di-sec-butoxy-bis(acetylacetonate)titanium, di-t-butoxy-bis(acetylacetonate)titanium, monoethoxy-tris(acetylacetonate)titanium, mono-n-propoxy-tris(acetylacetonate)titanium, mono-i-propoxy-tris(acetylacetonate)titanium, mono-n-butoxy-tris(acetylacetonate)titanium, mono-sec-butoxy-tris(acetylacetonate)titanium, mono-t-butoxy-tris(acetylacetonate)titanium, tetrakis(acetylacetonate)titanium, triethoxy-mono(ethyl acetoacetate)titanium, tri-n-propoxy-mono(ethyl acetoacetate)titanium, tri-i-propoxy-mono(ethyl acetoacetate)titanium, tri-n-butoxy-mono(ethyl acetoacetate)titanium, tri-sec-butoxy-mono(ethyl acetoacetate)titanium, tri-t-butoxy-mono(ethyl acetoacetate)titanium, diethoxy-bis(ethyl acetoacetate)titanium, di-n-propoxy-bis(ethyl acetoacetate)titanium, di-i-propoxy-bis(ethyl acetoacetate)titanium, di-n-butoxy-bis(ethyl acetoacetate)titanium, di-sec-butoxy-bis(ethyl acetoacetate)titanium, di-t-butoxy-bis(ethyl acetoacetate)titanium, monoethoxy-tris(ethyl acetoacetate)titanium, mono-n-propoxy-tris(ethyl acetoacetate)titanium, mono-i-propoxy-tris(ethyl acetoacetate)titanium, mono-n-butoxy-tris(ethyl acetoacetate)titanium, mono-sec-butoxy-tris(ethyl acetoacetate)titanium, mono-t-butoxy-tris(ethyl acetoacetate)titanium, tetrakis(ethyl acetoacetate)titanium, mono(acetylacetonate)tris(ethyl acetoacetate)titanium, bis(acetylacetonate)bis(ethyl acetoacetate)titanium, and tris(acetylacetonate) mono(ethyl acetoacetate)titanium; zirconium chelate compounds such as triethoxy-mono(acetylacetonate)zirconium, tri-n-propoxy-mono(acetylacetonate)zirconium, tri-i-propoxy-mono(acetylacetonate)zirconium, tri-n-butoxy-mono(acetylacetonate)zirconium, tri-sec-butoxy-mono(acetylacetonate)zirconium, tri-t-butoxy-mono(acetylacetonate)zirconium, diethoxy-bis(acetylacetonate)zirconium, di-n-propoxy-bis(acetylacetonate)zirconium, di-i-propoxy-bis(acetylacetonate)zirconium, di-n-butoxy-bis(acetylacetonate)zirconium, di-sec-butoxy-bis(acetylacetonate)zirconium, di-t-butoxy-bis(acetylacetonate)zirconium, monoethoxy-tris(acetylacetonate)zirconium, mono-n-propoxy-tris(acetylacetonate)zirconium, mono-i-propoxy-tris(acetylacetonate)zirconium, mono-n-butoxy-tris(acetylacetonate)zirconium, mono-sec-butoxy-tris(acetylacetonate)zirconium, mono-t-butoxy-tris(acetylacetonate)zirconium, tetrakis(acetylacetonate)zirconium, triethoxy-mono(ethyl acetoacetate)zirconium, tri-n-propoxy-mono(ethyl acetoacetate)zirconium, tri-i-propoxy-mono(ethyl acetoacetate)zirconium, tri-n-butoxy-mono(ethyl acetoacetate)zirconium, tri-sec-butoxy-mono(ethyl acetoacetate)zirconium, tri-t-butoxy-mono(ethyl acetoacetate)zirconium, diethoxy-bis(ethyl acetoacetate)zirconium, di-n-propoxy-bis(ethyl acetoacetate)zirconium, di-i-propoxy-bis(ethyl acetoacetate)zirconium, di-n-butoxy-bis(ethyl acetoacetate)zirconium, di-sec-butoxy-bis(ethyl acetoacetate)zirconium, di-t-butoxy-bis(ethyl acetoacetate)zirconium, monoethoxy-tris(ethyl acetoacetate)zirconium, mono-n-propoxy-tris(ethyl acetoacetate)zirconium, mono-i-propoxy-tris(ethyl acetoacetate)zirconium, mono-n-butoxy-tris(ethyl acetoacetate)zirconium, mono-sec-butoxy-tris(ethyl acetoacetate)zirconium, mono-t-butoxy-tris(ethyl acetoacetate)zirconium, tetrakis(ethyl acetoacetate)zirconium, mono(acetylacetonate)tris(ethyl acetoacetate)zirconium, bis(acetylacetonate)bis(ethyl acetoacetate)zirconium, and tris(acetylacetonate) mono(ethyl acetoacetate)zirconium; and aluminum chelate compounds such as tris(acetylacetonate)aluminum and tris(ethyl acetoacetate)aluminum.

Examples of the organic acid as the hydrolysis catalyst include, but are not limited to, acetic acid, propionic acid, butanoic acid, pentanoic acid, hexanoic acid, heptanoic acid, octanoic acid, nonanoic acid, decanoic acid, oxalic acid, maleic acid, methylmalonic acid, adipic acid, sebacic acid, gallic acid, butyric acid, mellitic acid, arachidonic acid, 2-ethylhexanoic acid, oleic acid, stearic acid, linoleic acid, linolenic acid, salicylic acid, benzoic acid, p-aminobenzoic acid, p-toluenesulfonic acid, benzenesulfonic acid, monochloroacetic acid, dichloroacetic acid, trichloroacetic acid, trifluoroacetic acid, formic acid, malonic acid, sulfonic acid, phthalic acid, fumaric acid, citric acid, and tartaric acid.

Examples of the inorganic acid as the hydrolysis catalyst include, but are not limited to, hydrochloric acid, nitric acid, sulfuric acid, hydrofluoric acid, and phosphoric acid.

Examples of the organic base as the hydrolysis catalyst include, but are not limited to, pyridine, pyrrole, piperazine, pyrrolidine, piperidine, picoline, trimethylamine, triethylamine, monoethanolamine, diethanolamine, dimethylmonoethanolamine, monomethyldiethanolamine, triethanolamine, diazabicyclooctane, diazabicyclononane, diazabicycloundecene, tetramethylammonium hydroxide, tetraethylammonium hydroxide, tetrapropylammonium hydroxide, tetrabutylammonium hydroxide, trimethylphenylammonium hydroxide, benzyltrimethylammonium hydroxide, and benzyltriethylammonium hydroxide.

Examples of the inorganic base as the hydrolysis catalyst include, but are not limited to, ammonia, sodium hydroxide, potassium hydroxide, barium hydroxide, and calcium hydroxide.

Among these catalysts, a metal chelate compound, an organic acid, and an inorganic acid are preferred. These catalysts may be used singly or in combination of two or more kinds thereof.

In particular, nitric acid can be suitably used as a hydrolysis catalyst in the present invention. The use of nitric acid enables an improvement in the storage stability of a reaction solution after the hydrolysis and condensation, and particularly enables suppression of a change in the molecular weight of a hydrolysis condensate. It is known that the stability of the hydrolysis condensate contained in the reaction solution depends on the pH of the solution. As a result of intensive studies, it has been found that the pH of the reaction solution falls in a stable range by use of an appropriate amount of nitric acid.

At the time of hydrolysis condensation, at least a part of silanol groups can be capped by containing an alcohol-based compound in the system. Capping is caused by the reaction between at least a part of silanol groups and the hydroxy group of the alcohol-based compound.

The reaction between silanol groups and the hydroxy groups of the alcohol-based compound is performed by bringing the uncapped hydrolysis condensate into contact with the alcohol-based compound. A modified polysiloxane containing capped silanol groups is prepared by performing the reaction at a temperature of 40 to 160° C. (e.g. 60° C.) for 0.1 to 48 hours (e.g. 24 hours). At this time, the alcohol-based compound as a capping agent can be used as an organic solvent.

After completion of the hydrolysis and condensation reactions, the reaction solution is used as is, or diluted or concentrated. The resultant reaction solution can be neutralized and treated with an ion exchange resin, and thus the hydrolysis catalyst, e.g. an acid or a base, used for the hydrolysis and condensation can be removed. Before or after such a treatment, alcohols: by-products, water, the used hydrolysis catalyst, and the like are removed from the reaction solution, for example, by distillation under reduced pressure. As a result, the amount of water mixed in the silicon-containing resist underlayer film-forming composition is reduced as much as possible.

The thus-prepared hydrolysis condensate (hereinafter, also referred to as “polysiloxane”) is in the form of a polysiloxane varnish dissolved in an organic solvent, which may be used as is as the silicon-containing resist underlayer film-forming composition described later. The resultant polysiloxane varnish may be subjected to solvent replacement, or may be appropriately diluted with a solvent. In a case where the storage stability of the resultant polysiloxane varnish is not poor, the organic solvent may be distilled off to achieve a solid content concentration of 100%.

The organic solvent used for solvent replacement, dilution, or the like of the polysiloxane varnish may be identical to or different from the organic solvent used for the hydrolysis and condensation reactions of the hydrolyzable silane mixture. The solvent for dilution is not particularly limited, and one kind or two or more kinds of solvents may be arbitrarily selected and used.

The silicon-containing resist underlayer film-forming composition of the present invention can contain, in addition to the hydrolysis condensate (polysiloxane) of the hydrolyzable silane mixture, an organic solvent, a specific additive having a chemical structure containing a cation AX⁺ and an anion AZ⁻ (compound A), and other components.

### <Organic Solvent>

The organic solvent used in the silicon-containing resist underlayer film-forming composition of the present invention can be used without particular limitation as long as it is an organic solvent capable of dissolving the solid content in the silicon-containing resist underlayer film-forming composition.

Such an organic solvent is not limited as long as it dissolves a hydrolysis condensate of the hydrolyzable silane mixture, a specific additive (compound A), and other components.

Examples of the organic solvent include the alcohol-based compounds described above.

Also, examples of the organic solvent include methyl cellosolve acetate, ethyl cellosolve acetate, propylene glycol, propylene glycol monomethyl ether (1-methoxy-2-propanol), propylene glycol monoethyl ether (1-ethoxy-2-propanol), methyl isobutyl carbinol, propylene glycol monobutyl ether, propylene glycol monomethyl ether acetate (1-methoxy-2-propanol monoacetate), propylene glycol monoethyl ether acetate, propylene glycol monopropyl ether acetate, propylene glycol monobutyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethylene glycol monomethyl ether, ethylene glycol monoethyl ether, ethylene glycol monopropyl ether, ethylene glycol monobutyl ether, ethylene glycol monomethyl ether acetate, ethylene glycol monoethyl ether acetate, ethylene glycol monopropyl ether acetate, ethylene glycol monobutyl ether acetate, diethylene glycol dimethyl ether, diethylene glycol diethyl ether, diethylene glycol dipropyl ether, diethylene glycol dibutyl ether propylene glycol monomethyl ether, propylene glycol dimethyl ether, propylene glycol diethyl ether, propylene glycol dipropyl ether, propylene glycol dibutyl ether, ethyl lactate, propyl lactate, isopropyl lactate, butyl lactate, isobutyl lactate, methyl formate, ethyl formate, propyl formate, isopropyl formate, butyl formate, isobutyl formate, amyl formate, isoamyl formate, methyl acetate, ethyl acetate, amyl acetate, isoamyl acetate, hexyl acetate, methyl propionate, ethyl propionate, propyl propionate, isopropyl propionate, butyl propionate, isobutyl propionate, methyl butyrate, ethyl butyrate, propyl butyrate, isopropyl butyrate, butyl butyrate, isobutyl butyrate, ethyl hydroxyacetate, ethyl 2-hydroxy-2-methylpropionate, methyl 3-methoxy-2-methylpropionate, methyl 2-hydroxy-3-methylbutyrate, ethyl methoxyacetate, ethyl ethoxyacetate, methyl 3-methoxypropionate, ethyl 3-ethoxypropionate, ethyl 3-methoxypropionate, 3-methoxybutyl acetate, 3-methoxypropyl acetate, 3-methyl-3-methoxybutyl acetate, 3-methyl-3-methoxybutylpropionate, 3-methyl-3-methoxybutylbutyrate, methyl acetoacetate, toluene, xylene, methyl ethyl ketone, methyl propyl ketone, methyl butyl ketone, 2-heptanone, 3-heptanone, 4-heptanone, cyclohexanone, N,N-dimethylformamide, N-methylacetamide, N,N-dimethylacetamide, N-methyl-2-pyrrolidone, 4-methyl-2-pentanol, and γ-butyrolactone, and the organic solvents may be used singly or in combination of two or more kinds thereof.

### <Specific Additive (Compound A)>

By further adding a specific additive having a chemical structure containing a cation AX⁺ and an anion AZ⁻ (compound A) to the silicon-containing resist underlayer film-forming composition containing a hydrolysis condensate (polysiloxane) of the hydrolyzable silane mixture, a silicon-containing resist underlayer film exhibiting more excellent solubility in an alkaline solution (basic chemical solution) can be formed.

The specific additive (compound A) is a compound having a chemical structure containing a cation AX⁺ and an anion AZ⁻, in which the anion has a molecular weight of 65 or more.

In the specific additive (compound A), “cation” means an atom having a positive charge or an atomic group having a positive charge, and “anion” means an atom having a negative charge or an atomic group having a negative charge.

It is presumed that the reason why the solubility of the silicon-containing resist underlayer film to the alkaline solution (basic chemical solution) is increased by containing the specific additive (compound A) in the silicon-containing resist underlayer film is that the presence of anionic species in the specific additive (compound A) between the hydrolysis condensates (polymers) inhibits the bonding at which the hydrolysis condensates are crosslinked, or the anionic species themselves are bonded and capped, so that three-dimensional crosslinking does not proceed.

The anion AZ⁻ has a molecular weight of more preferably 65 or more from the viewpoint of suppressing condensation. It has a molecular weight of more preferably 500 or less from the viewpoint of maintaining dry etching resistance.

### <<Anion AZ^{->>}

In the compound A, the anion AZ⁻ may be present outside or inside the molecule of the cation AX⁺.

The phrase “the anion AZ⁻ is present outside the molecule of the cation AX⁺” refers to a state in which the anion AZ⁻ is not bonded to the cation AX⁺ via a covalent bond and is present as a structural unit independent of the cation AX⁺. Examples of the form of the compound A as described above include salts. Hereinafter, an anion present outside the molecule of the cation is also referred to as a counter anion.

In the compound A, the anion AZ⁻ may be bonded to the cation AX⁺ via a covalent bond. That is, the form of the compound A may be an intramolecular salt (also referred to as a zwitterion).

The type of the anion AZ⁻ is not particularly limited as long as the condition that the anion has a molecular weight of 65 or more is satisfied, and examples thereof include anions having chemical structures represented by the following (A) to (E).

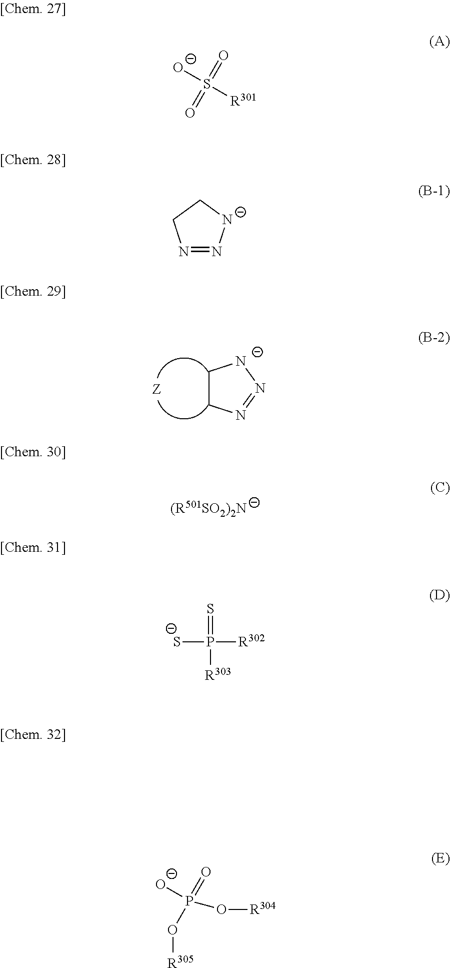

wherein in Formulae (A) to (E), R³⁰¹ represents an optionally substituted alkyl group, an optionally substituted aryl group, an optionally substituted halogenated alkyl group, an optionally substituted aralkyl group, or an organic group containing an ester bond (—C(═O)—O— or —O—C(═O)—), or a combination thereof,
Z represents an aromatic ring, a cyclic alkane, or a cyclic alkene of a non-aromatic ring,
R⁵⁰¹ represents an alkyl group in which some or all may be substituted with a fluorine atom,
R³⁰² and R³⁰³ each independently represent an alkyl group, and
R³⁰⁴ and R³⁰⁵ each independently represent an alkyl group.

Specific examples of the alkyl group, the aryl group, the halogenated alkyl group, and the aralkyl group include those described above. Specific examples of the substituent that may be substituted with the alkyl group or the like include those described above.

Examples of the specific additive (compound A) include a compound having a sulfonate anion represented by Formula (A).

The compound having a sulfonate anion represented by Formula (A) may be not only a compound having an anion represented by Formula (A) outside the molecule, but also a compound having an anion represented by Formula (A) inside the molecule, like sulfobetaine such as lauryl sulfobetaine or myristyl sulfobetaine (see the following compounds (Add-6), (Add-7)).

Examples of the specific additive (compound A) include a compound having an anion containing a triazole skeleton represented by Formula (B-1) or Formula (B-2).

In Formula (B-2), Z represents an aromatic ring, a cyclic alkane or a cyclic alkene of a non-aromatic ring having 1 to 6 carbon atoms.

As the specific additive (compound A), a compound having an anion represented by Formula (B-2) is preferable, and in particular, Z is preferably an aromatic ring in Formula (B-2). That is, a preferred embodiment of the specific additive (compound A) includes, for example, a compound having an anion containing a benzotriazole skeleton represented by the following (b-1).

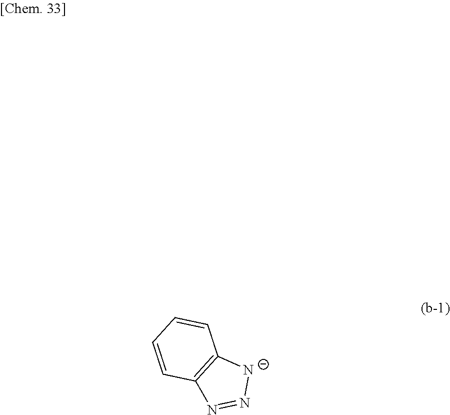

Examples of the specific additive (compound A) include a compound represented by Formula (C).

In Formula (C), R⁵⁰¹ represents an alkyl group having 1 to 4 carbon atoms, a fluoroalkyl group or a perfluoroalkyl group in which a part or all of the alkyl group is substituted with a fluorine atom.

Among them, R⁵⁰¹ is preferably a CF₃ group or a C₄F₉ group. In particular, the specific additive (compound A) is more preferably, for example, a compound having an anion of bis(trifluoromethanesulfonyl)imide represented by the following (c-1).

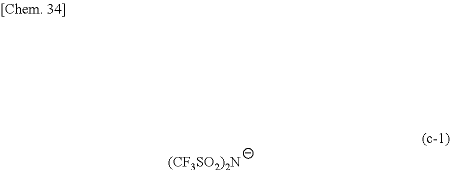

Examples of the specific additive (compound A) include a compound having a thiophosphate anion represented by Formula (D).

Examples of the specific additive (compound A) include a compound having a phosphate anion represented by Formula (E).

Specific examples of the specific additive (compound A) include, but are not limited to, compounds represented by the following Formulae (Add-1) to (Add-12).

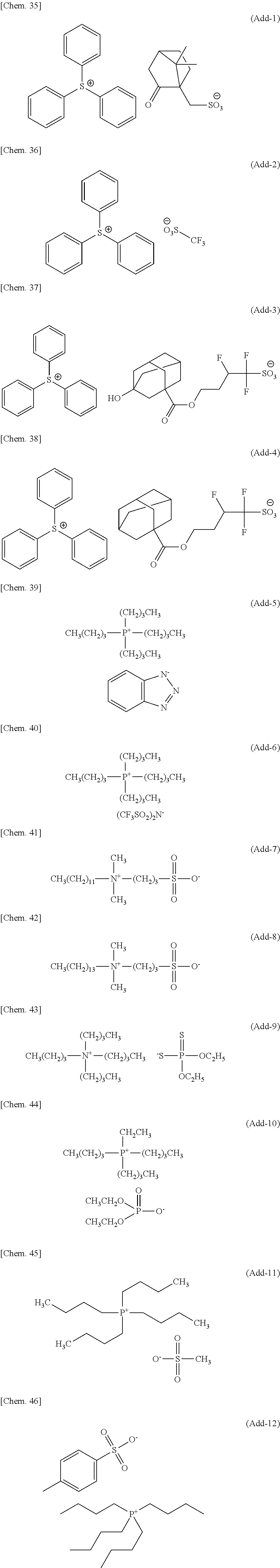

When the silicon-containing resist underlayer film-forming composition of the present invention contains a specific additive, the content thereof can be 1 to 30 parts by mass relative to 100 parts by mass of the hydrolysis condensate.

### <Other Components (Other Additives)>

In the silicon-containing resist underlayer film-forming composition of the present invention, various additives which are other components other than the specific additives (also referred to as other additives) can be blended depending on the use of the composition.

Examples of other components (other additives) that can be blended in the silicon-containing resist underlayer film-forming composition include known additives incorporated in materials (compositions) for forming various films that can be used in the production of a semiconductor device, such as a resist underlayer film, an antireflection film, and a pattern inversion film, such as a curing catalyst (e.g. an ammonium salt, a phosphine, a phosphonium salt, a sulfonium salt, or a nitrogen-containing silane compound), a crosslinking agent, a crosslinking catalyst, a stabilizer (e.g. an organic acid, water, or an alcohol), an organic polymer, an acid generator, a surfactant (e.g. a nonionic surfactant, an anionic surfactant, a cationic surfactant, a silicon-based surfactant, a fluorine-based surfactant, or an UV-curable surfactant), a pH adjuster, a rheology controlling agent, and an adhesion aid.

Hereinafter, various additives will be exemplified, but the additives are not limited thereto.

### <<Curing Catalyst>>

The curing catalyst may be, for example, an ammonium salt, a phosphine, a phosphonium salt, or a sulfonium salt. The salt described below as a curing catalyst may be added in the form of a salt, or may be a compound that forms a salt in the composition (i.e. a compound that forms a salt in the system, but is in a form different from the salt during addition).

Examples of the ammonium salt include a quaternary ammonium salt having a structure represented by Formula (D-1):

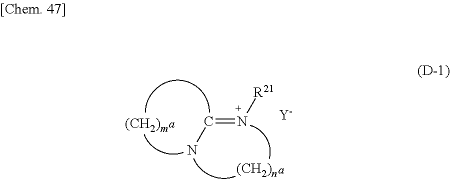

wherein m represents an integer of 2 to 11, n represents an integer of 2 to 3, R²¹ represents an alkyl group or an aryl group, and Y⁻ represents an anion;
a quaternary ammonium salt having a structure represented by Formula (D-2):

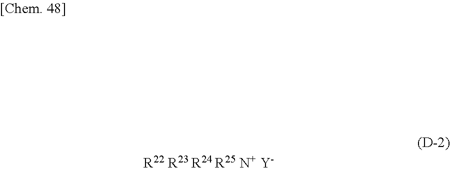

wherein R²², R²³, R²⁴, and R²⁵ represent an alkyl group or an aryl group, N represents a nitrogen atom, Y⁻ represents an anion, and R²², R²³, R²⁴, and R²⁵ are each bonded to the nitrogen atom by a C—N bond;
a quaternary ammonium salt having a structure represented by Formula (D-3):

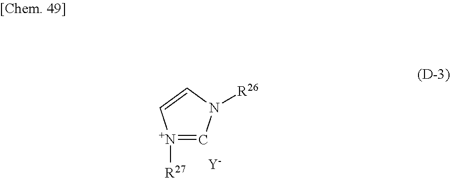

wherein R²⁶ and R²⁷ represent an alkyl group or an aryl group, N represents a nitrogen atom, and Y-represents an anion;
a quaternary ammonium salt having a structure represented by Formula (D-4):

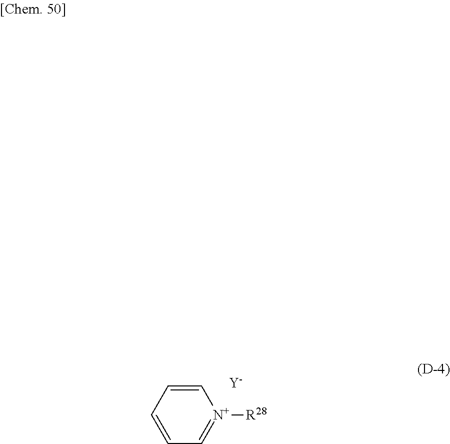

wherein R²⁸ represents an alkyl group or an aryl group, N represents a nitrogen atom, and Y⁻ represents an anion;
a quaternary ammonium salt having a structure represented by Formula (D-5):

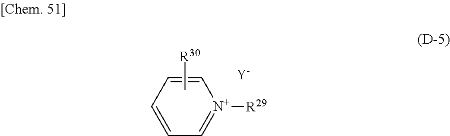

wherein R²⁹ and R³⁰ represent an alkyl group or an aryl group, N represents a nitrogen atom, and Y⁻ represents an anion; and
a tertiary ammonium salt having a structure represented by Formula (D-6):

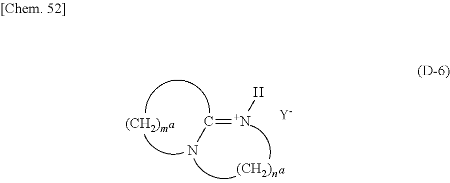

wherein m represents an integer of 2 to 11, n represents an integer of 2 to 3, H represents a hydrogen atom, N represents a nitrogen atom, and Y⁻ represents an anion.

Examples of the phosphonium salt include a quaternary phosphonium salt represented by formula (D-7):

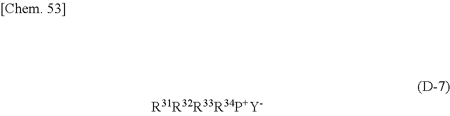

wherein R³¹, R³², R³³, and R³⁴ represent an alkyl group or an aryl group, P represents a phosphorus atom, Y⁻ represents an anion, and R³¹, R³², R³³, and R³⁴ are each bonded to the phosphorus atom by a C—P bond.

Examples of the sulfonium salt include a tertiary sulfonium salt represented by formula (D-8):

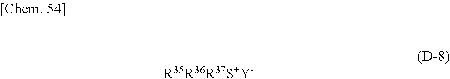

wherein R³⁵, R³⁶, and R³⁷ represent an alkyl group or an aryl group, S represents a sulfur atom, Y⁻ represents an anion, and R³⁵, R³⁶, and R³⁷ are each bonded to the sulfur atom by a C—S bond.

The compound of Formula (D-1) is a quaternary ammonium salt derived from an amine, m represents an integer of 2 to 11, and n represents an integer of 2 to 3. R²¹ of this quaternary ammonium salt represents an alkyl group having 1 to 18 and preferably 2 to 10 carbon atoms or an aryl group having 6 to 18 carbon atoms, and examples thereof include a linear alkyl group such as an ethyl group, a propyl group, or a butyl group, a benzyl group, a cyclohexyl group, a cyclohexylmethyl group, and a dicyclopentadienyl group. Further, examples of the anion (Y⁻) include halide ions, such as chlorine ion (Cl⁻), bromine ion (Br⁻), and iodine ion (I⁻); and acid groups, such as carboxylate (—COO⁻), sulfonate (—SO₃⁻), and alcoholate (—O⁻).

The compound of Formula (D-2) is a quaternary ammonium salt represented by R²²R²³R²⁴R²⁵N⁺Y⁻. R²², R²³, R²⁴, and R²⁵ of this quaternary ammonium salt are each an alkyl group having 1 to 18 carbon atoms or an aryl group having 6 to 18 carbon atoms. Examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃⁻), and alcoholate (—O⁻). The quaternary ammonium salt is commercially available, and examples of the quaternary ammonium salt include tetramethylammonium acetate, tetrabutylammonium acetate, triethylbenzylammonium chloride, triethylbenzylammonium bromide, trioctylmethylammonium chloride, tributylbenzylammonium chloride, and trimethylbenzylammonium chloride.

The compound of Formula (D-3) is a quaternary ammonium salt derived from a 1-substituted imidazole, the number of carbon atoms of R²⁶ and R²⁷ is 1 to 18, and the total number of carbon atoms of R²⁶ and R²⁷ is preferably 7 or more. Examples of R²⁶ include a methyl group, an ethyl group, a propyl group, a phenyl group, and a benzyl group, and examples of R²⁷ include a benzyl group, an octyl group, and an octadecyl group. Examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃⁻), and alcoholate (—O⁻). Although this compound is commercially available, the compound may be produced through, for example, reaction between an imidazole compound (e.g. 1-methylimidazole or 1-benzylimidazole) and a halogenated alkyl or a halogenated aryl, such as benzyl bromide or methyl bromide.

The compound of Formula (D-4) is a quaternary ammonium salt derived from pyridine. R²⁸ is an alkyl group having 1 to 18 carbon atoms, preferably 4 to 18 carbon atoms, or an aryl group having 6 to 18 carbon atoms. Examples thereof include a butyl group, an octyl group, a benzyl group, and a lauryl group. Examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃⁻), and alcoholate (—O⁻). Although this compound is commercially available, the compound may be produced through, for example, reaction between pyridine and a halogenated alkyl or a halogenated aryl, such as lauryl chloride, benzyl chloride, benzyl bromide, methyl bromide, or octyl bromide. Examples of this compound include N-laurylpyridinium chloride and N-benzylpyridinium bromide.

The compound of Formula (D-5) is a quaternary ammonium salt derived from a substituted pyridine, such as picoline. R²⁹ is an alkyl group having 1 to 18 carbon atoms, preferably 4 to 18 carbon atoms, or an aryl group having 6 to 18 carbon atoms. Examples thereof include a methyl group, an octyl group, a lauryl group, and a benzyl group. R³⁰ is, an alkyl group having 1 to 18 carbon atoms or an aryl group having 6 to 18 carbon atoms, and for example, when the compound represented by Formula (D-5) is quaternary ammonium derived from picoline, R³⁰ is a methyl group. Examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃⁻), and alcoholate (—O⁻). Although this compound is commercially available, the compound may be produced through, for example, reaction between a substituted pyridine (e.g. picoline) and a halogenated alkyl or a halogenated aryl, such as methyl bromide, octyl bromide, lauryl chloride, benzyl chloride, or benzyl bromide. Examples of this compound include N-benzylpicolinium chloride, N-benzylpicolinium bromide, and N-laurylpicolinium chloride.

The compound of Formula (D-6) is a tertiary ammonium salt derived from an amine, m represents an integer of 2 to 11, and n represents an integer of 2 to 3. Further, examples of the anion (Y⁻) include halide ions, such as chlorine ion (Cl⁻), bromine ion (Br⁻), and iodine ion (I⁻); and acid groups, such as carboxylate (—COO⁻), sulfonate (—SO₃⁻), and alcoholate (—O⁻). The compound may be produced through reaction between an amine and a weak acid, such as a carboxylic acid or phenol. Examples of the carboxylic acid include formic acid and acetic acid. When formic acid is used, the anion (Y⁻) is (HCOO⁻). When acetic acid is used, the anion (Y⁻) is (CH₃COO⁻). When phenol is used, the anion (Y⁻) is (C₆H₅O⁻).

The compound of Formula (D-7) is a quaternary phosphonium salt having a structure of R³¹R³²R³³R³⁴P⁺Y⁻. R³¹, R³², R³³, and R³⁴ are an alkyl group having 1 to 18 carbon atoms or an aryl group having 6 to 18 carbon atoms, preferably three of the four substituent groups R³¹ to R³⁴ are an unsubstituted phenyl group or a substituted phenyl group, and for example, a phenyl group or a tolyl group can be exemplified, and the remaining one is an alkyl group having 1 to 18 carbon atoms or an aryl group having 6 to 18 carbon atoms. Further, examples of the anion (Y⁻) include halide ions, such as chlorine ion (Cl⁻), bromine ion (Br⁻), and iodine ion (I); and acid groups, such as carboxylate (—COO⁻), sulfonate (—SO₃⁻), and alcoholate (—O⁻). This compound is commercially available, and examples of the compound include tetraalkylphosphonium halides, such as tetra-n-butylphosphonium halide and tetra-n-propylphosphonium halide; trialkylbenzylphosphonium halides, such as triethylbenzylphosphonium halide; triphenylmonoalkylphosphonium halides, such as triphenylmethylphosphonium halide and triphenylethylphosphonium halide; triphenylbenzylphosphonium halide; tetraphenylphosphonium halide; tritolylmonoarylphosphonium halide; or tritolylmonoalkylphosphonium halide, where the halogen atom is a chlorine atom or a bromine atom. Particularly preferred are triphenylmonoalkylphosphonium halides, such as triphenylmethylphosphonium halide and triphenylethylphosphonium halide; triphenylmonoarylphosphonium halides, such as triphenylbenzylphosphonium halide; tritolylmonoarylphosphonium halides, such as tritolylmonophenylphosphonium halide; and tritolylmonoalkylphosphonium halides, such as tritolylmonomethylphosphonium halide, where the halogen atom is a chlorine atom or a bromine atom.

Examples of the phosphine compound include primary phosphines, such as methylphosphine, ethylphosphine, propylphosphine, isopropylphosphine, isobutylphosphine, and phenylphosphine; secondary phosphines, such as dimethylphosphine, diethylphosphine, diisopropylphosphine, diisoamylphosphine, and diphenylphosphine; and tertiary phosphines, such as trimethylphosphine, triethylphosphine, triphenylphosphine, methyldiphenylphosphine, and dimethylphenylphosphine.

The compound of Formula (D-8) is a tertiary sulfonium salt having a structure of R³⁵R³⁶R³⁷S⁺Y⁻. R³⁵, R³⁶, and R³⁷ are an alkyl group having 1 to 18 carbon atoms or an aryl group having 6 to 18 carbon atoms, preferably two of the three substituent groups R³⁵ to R³⁷ are an unsubstituted phenyl group or a substituted phenyl group, and for example, a phenyl group or a tolyl group can be exemplified, and the remaining one is an alkyl group having 1 to 18 carbon atoms or an aryl group having 6 to 18 carbon atoms. Examples of the anion (Y⁻) include halide ions, such as chlorine ion (Cl⁻), bromine ion (Br⁻), and iodine ion (I⁻); and acid groups, such as carboxylate (—COO⁻), sulfonate (—SO₃⁻), alcoholate (—O⁻), maleate anion, and nitrate anion. This compound is commercially available, and examples of the compound include trialkylsulfonium halides, such as tri-n-butylsulfonium halide and tri-n-propylsulfonium halide; dialkylbenzylsulfonium halides, such as diethylbenzylsulfonium halide; diphenylmonoalkylsulfonium halides, such as diphenylmethylsulfonium halide and diphenylethylsulfonium halide; triphenylsulfonium halides, where the halogen atom is a chlorine atom or a bromine atom; trialkylsulfonium carboxylates, such as tri-n-butylsulfonium carboxylate and tri-n-propylsulfonium carboxylate; dialkylbenzylsulfonium carboxylates, such as diethylbenzylsulfonium carboxylate; diphenylmonoalkylsulfonium carboxylates, such as diphenylmethylsulfonium carboxylate and diphenylethylsulfonium carboxylate; and triphenylsulfonium carboxylate. Triphenylsulfonium halide and triphenylsulfonium carboxylate are preferably used.

In addition, a nitrogen-containing silane compound may be added as a curing catalyst in the present invention. Examples of the nitrogen-containing silane compound include silane compounds containing an imidazole ring, such as N-(3-triethoxysilylpropyl)-4,5-dihydroimidazole.

When a curing catalyst is used, the content thereof is 0.01 parts by mass to 10 parts by mass, 0.01 parts by mass to 5 parts by mass, or 0.01 parts by mass to 3 parts by mass relative to 100 parts by mass of the hydrolysis condensate.

### <<Stabilizer>>

The stabilizer may be added for the purpose of stabilizing the hydrolysis condensate of the hydrolyzable silane mixture, or the like. As a specific example of the stabilizer, an organic acid, alcohol, or a combination thereof can be added.

Examples of the organic acid include oxalic acid, malonic acid, methylmalonic acid, succinic acid, maleic acid, malic acid, tartaric acid, phthalic acid, citric acid, glutaric acid, lactic acid, and salicylic acid. Among these organic acids, oxalic acid and maleic acid are preferred. When the organic acid is added, the amount of the organic acid added is 0.1 to 5.0 mass % relative to the mass of the hydrolysis condensate of the hydrolyzable silane mixture. These organic acids may also serve as pH adjusters.

The alcohol is preferably an alcohol that is easily scattered (volatilized) by heating after the application, and examples of the alcohol include methanol, ethanol, propanol, i-propanol, and butanol. When an alcohol is added, the amount of the alcohol added may be 1 part by mass to 20 parts by mass relative to 100 parts by mass of the silicon-containing resist underlayer film-forming composition.

### <<Organic Polymer>>

Addition of the organic polymer to the silicon-containing resist underlayer film-forming composition enables adjustment of the dry etching rate (the amount of reduction in film thickness per unit time), attenuation coefficient, refractive index, and the like of a film (resist underlayer film) formed from the composition. The organic polymer is not particularly limited, and is appropriately selected from various organic polymers (polycondensation polymer and addition polymerization polymer) depending on the purpose of addition thereof.

Specific examples of the organic polymer include addition polymerization polymers and polycondensation polymers, such as polyester, polystyrene, polyimide, acrylic polymer, methacrylic polymer, polyvinyl ether, phenol novolac, naphthol novolac, polyether, polyamide, and polycarbonate.

In the present invention, an organic polymer containing an aromatic ring or a heteroaromatic ring such as a benzene ring, a naphthalene ring, an anthracene ring, a triazine ring, a quinoline ring, or a quinoxaline ring, which functions as a light absorption site, can also be suitably used when such a function is required. Specific examples of such an organic polymer include, but are not limited to, addition polymerization polymers containing, as structural units, addition polymerizable monomers, such as benzyl acrylate, benzyl methacrylate, phenyl acrylate, naphthyl acrylate, anthryl methacrylate, anthrylmethyl methacrylate, styrene, hydroxystyrene, benzyl vinyl ether, and N-phenylmaleimide, and polycondensation polymers, such as phenol novolac and naphthol novolac.

When an addition polymerization polymer is used as an organic polymer, the polymer may be either a homopolymer or a copolymer.

An addition polymerizable monomer is used for the production of the addition polymerization polymer. Specific examples of the addition polymerizable monomer include, but are not limited to, acrylic acid, methacrylic acid, an acrylate ester compound, a methacrylate ester compound, an acrylamide compound, a methacrylamide compound, a vinyl compound, a styrene compound, a maleimide compound, maleic anhydride, and acrylonitrile.

Specific examples of the acrylate ester compound include, but are not limited to, methyl acrylate, ethyl acrylate, normal hexyl acrylate, i-propyl acrylate, cyclohexyl acrylate, benzyl acrylate, phenyl acrylate, anthrylmethyl acrylate, 2-hydroxyethyl acrylate, 3-chloro-2-hydroxypropyl acrylate, 2-hydroxypropyl acrylate, 2,2,2-trifluoroethyl acrylate, 2,2,2-trichloroethyl acrylate, 2-bromoethyl acrylate, 4-hydroxybutyl acrylate, 2-methoxyethyl acrylate, tetrahydrofurfuryl acrylate, 2-methyl-2-adamantyl acrylate, 5-acryloyloxy-6-hydroxynorbornene-2-carboxylic-6-lactone, 3-acryloxypropyltriethoxysilane, and glycidyl acrylate.

Specific examples of the methacrylate ester compound include, but are not limited to, methyl methacrylate, ethyl methacrylate, normal hexyl methacrylate, i-propyl methacrylate, cyclohexyl methacrylate, benzyl methacrylate, phenyl methacrylate, anthrylmethyl methacrylate, 2-hydroxyethyl methacrylate, 2-hydroxypropyl methacrylate, 2,2,2-trifluoroethyl methacrylate, 2,2,2-trichloroethyl methacrylate, 2-bromoethyl methacrylate, 4-hydroxybutyl methacrylate, 2-methoxyethyl methacrylate, tetrahydrofurfuryl methacrylate, 2-methyl-2-adamantyl methacrylate, 5-methacryloyloxy-6-hydroxynorbornene-2-carboxylic-6-lactone, 3-methacryloxypropyltriethoxysilane, glycidyl methacrylate, 2-phenylethyl methacrylate, hydroxyphenyl methacrylate, and bromophenyl methacrylate.

Specific examples of the acrylamide compound include, but are not limited to, acrylamide, N-methylacrylamide, N-ethylacrylamide, N-benzylacrylamide, N-phenylacrylamide, N,N-dimethylacrylamide, and N-anthrylacrylamide.

Specific examples of the methacrylamide compound include, but are not limited to, methacrylamide, N-methylmethacrylamide, N-ethylmethacrylamide, N-benzylmethacrylamide, N-phenylmethacrylamide, N,N-dimethylmethacrylamide, and N-anthrylmethacrylamide.

Specific examples of the vinyl compound include, but are not limited to, vinyl alcohol, 2-hydroxyethyl vinyl ether, methyl vinyl ether, ethyl vinyl ether, benzyl vinyl ether, vinyl acetate vinyltrimethoxysilane, 2-chloroethyl vinyl ether, 2-methoxyethyl vinyl ether, vinylnaphthalene, and vinylanthracene.

Specific examples of the styrene compound include, but are not limited to, styrene, hydroxystyrene, chlorostyrene, bromostyrene, methoxystyrene, cyanostyrene, and acetylstyrene.

Examples of the maleimide compound include, but are not limited to, maleimide, N-methylmaleimide, N-phenylmaleimide, N-cyclohexylmaleimide, N-benzylmaleimide, and N-hydroxyethylmaleimide.

When a polycondensation polymer is used as the polymer, the polymer is, for example, a polycondensation polymer composed of a glycol compound and a dicarboxylic acid compound. Examples of the glycol compound include diethylene glycol, hexamethylene glycol, and butylene glycol. Examples of the dicarboxylic acid compound include succinic acid, adipic acid, terephthalic acid, and maleic anhydride. Further, examples of the polymer include, but are not limited to, polyesters, polyamides, and polyimides, such as polypyromellitimide, poly(p-phenyleneterephthalamide), polybutylene terephthalate, and polyethylene terephthalate.

When the organic polymer contains a hydroxy group, the hydroxy group may be crosslinked with a hydrolysis condensate, or the like.

The organic polymer may ordinarily have a weight-average molecular weight of 1,000 to 1,000,000. From the viewpoint of sufficiently achieving the effect of the polymer function and preventing the precipitation of the polymer in the composition, the weight-average molecular weight of the organic polymer to be added may be, for example, 3,000 to 300,000, 5,000 to 300,000, or 10,000 to 200,000.

The organic polymer may be used singly or in combination of two or more kinds thereof.

When the resist underlayer film-forming composition of the present invention contains an organic polymer, the content of the organic polymer cannot be univocally determined, since the content should be appropriately determined in consideration of the function of the organic polymer or the like. Ordinarily, the content may be 1 to 200 mass % relative to the mass of the hydrolysis condensate of the hydrolyzable silane mixture. From the viewpoint of preventing the precipitation of the organic polymer in the composition and the like, the content may be, for example, 100 mass % or less, preferably 50 mass % or less, and more preferably 30 mass % or less. From the viewpoint of sufficiently achieving the effect of the polymer and the like, the content may be, for example, 5 mass % or more, preferably 10 mass % or more, more preferably 30 mass % or more.

### <<Acid Generator>>

Examples of the acid generator include a thermal acid generator and a photoacid generator, and a photoacid generator may be preferably used.

Examples of the photoacid generator include, but are not limited to, an onium salt compound, a sulfonimide compound, and a disulfonyldiazomethane compound. Examples of the thermal acid generator include, but are not limited to, tetramethylammonium nitrate.

Specific examples of the onium salt compound include, but are not limited to, iodonium salt compounds, such as diphenyliodonium hexafluorophosphate, diphenyliodonium trifluoromethanesulfonate, diphenyliodonium nonafluoro normal butanesulfonate, diphenyliodonium perfluoro normal octanesulfonate, diphenyliodonium camphorsulfonate, bis(4-t-butylphenyl)iodonium camphorsulfonate, and bis(4-t-butylphenyl)iodonium trifluoromethanesulfonate; and sulfonium salt compounds, such as triphenylsulfonium hexafluoroantimonate, triphenylsulfonium nonafluoro normal butanesulfonate, triphenylsulfonium camphorsulfonate, triphenylsulfonium trifluoromethanesulfonate, triphenylsulfonium nitrate, triphenylsulfonium trifluoroacetate, triphenylsulfonium maleate, and triphenylsulfonium chloride.

Specific examples of the sulfonimide compound include, but are not limited to, N-(trifluoromethanesulfonyloxy)succinimide, N-(nonafluoronormalbutanesulfonyloxy)succinimide, N-(camphorsulfonyloxy)succinimide, and N-(trifluoromethanesulfonyloxy)naphthalimide.

Specific examples of the disulfonyl diazomethane compound include, but are not limited to, bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyl diazomethane.

When the silicon-containing resist underlayer film-forming composition of the present invention contains an acid generator, the content of the acid generator cannot be univocally determined, since the amount should be appropriately determined in consideration of the type of the acid generator and the like. Ordinarily, the content of the acid generator is 0.01 to 5 mass % relative to the mass of the hydrolysis condensate of the hydrolyzable silane mixture. From the viewpoint of preventing the precipitation of the acid generator in the composition and the like, the content is preferably 3 mass % or less, more preferably 1 mass % or less. From the viewpoint of sufficiently achieving the effect of the acid generator and the like, the content is preferably 0.1 mass % or more, more preferably 0.5 mass % or more.

The acid generators may be used singly or in combination of two or more kinds thereof. A photoacid generator and a thermal acid generator may be used in combination.

### <<Surfactant>>

When the silicon-containing resist underlayer film-forming composition is applied to a substrate, a surfactant is effective in prevention of formation of pinholes, striations, and the like. Examples of the surfactant include a nonionic surfactant, an anionic surfactant, a cationic surfactant, a silicon-based surfactant, a fluorine-based surfactant, and a UV-curable surfactant. Specific examples of the surfactant include, but are not limited to, nonionic surfactants, for example, polyoxyethylene alkyl ethers, such as polyoxyethylene lauryl ether, polyoxyethylene stearyl ether, polyoxyethylene cetyl ether, and polyoxyethylene oleyl ether, polyoxyethylene alkylaryl ethers, such as polyoxyethylene octylphenol ether and polyoxyethylene nonylphenol ether, polyoxyethylene-polyoxypropylene block copolymers, sorbitan fatty acid esters, such as sorbitan monolaurate, sorbitan monopalmitate, sorbitan monostearate, sorbitan monooleate, sorbitan trioleate, and sorbitan tristearate, polyoxyethylene sorbitan fatty acid esters, such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorine-based surfactants, such as trade names EFTOP (registered trademark) EF301, EF303, and EF352 (manufactured by Mitsubishi Materials Electronic Chemicals Co., Ltd. (former Tohkem Products Corporation)), trade names MEGAFACE (registered trademark) F171, F173, R-08, R-30, R-30N, and R-40 LM (manufactured by DIC Corporation), Fluorad FC430 and FC431 (manufactured by 3M Japan Limited), trade name Asahi Guard (registered trademark) AG710 (manufactured by AGC Inc.), and trade names SURFLON (registered trademark) S-382, SC101, SC102, SC103, SC104, SC105, and SC106 (manufactured by AGC Seimi Chemical Co., Ltd.); and Organosiloxane Polymer KP341 (manufactured by Shin-Etsu Chemical Co., Ltd.).

The surfactants may be used singly or in combination of two or more kinds thereof.

When the silicon-containing resist underlayer film-forming composition contains a surfactant, the content of the surfactant is ordinarily 0.0001 to 5 mass %, preferably 0.001 to 4 mass %, and more preferably 0.01 to 3 mass % relative to the mass of the hydrolysis condensate of the hydrolyzable silane mixture.

### <<Rheology Controlling Agent>>

The rheology controlling agent is added mainly for the purpose of improving the fluidity of the silicon-containing resist underlayer film-forming composition, particularly in a baking process, improving the uniformity of the thickness of a film to be formed, or improving the fillability of the composition into holes. Specific examples of the rheology controlling agent include phthalic acid derivatives, such as dimethyl phthalate, diethyl phthalate, di-i-butyl phthalate, dihexyl phthalate, and butyl-1-decyl phthalate; adipic acid derivatives, such as di-normal butyl adipate, di-i-butyl adipate, di-i-octyl adipate, and octyl decyl adipate; maleic acid derivatives, such as di-normal butyl maleate, diethyl maleate, and dinonyl maleate; oleic acid derivatives, such as methyl oleate, butyl oleate, and tetrahydrofurfuryl oleate; and stearic acid derivatives, such as normal butyl stearate and glyceryl stearate.

When such a rheology controlling agent is used, the amount of the rheology controlling agent added is ordinarily less than 30 mass % relative to the total solid content of the silicon-containing resist underlayer film-forming composition.

### <<Adhesion Aid>>

The adhesion aid is added for the purpose of mainly improving the adhesion between a substrate or a resist and a film (silicon-containing resist underlayer film) formed from the silicon-containing resist underlayer film-forming composition, in particular, suppressing or preventing the peeling of the resist during development. Specific examples of the adhesion aid include chlorosilanes, such as trimethylchlorosilane, dimethylvinylchlorosilane, methyldiphenylchlorosilane, and chloromethyldimethylchlorosilane; alkoxysilanes, such as trimethylmethoxysilane, dimethyldiethoxysilane, methyldimethoxysilane, and dimethylvinylethoxysilane; silazanes, such as hexamethyldisilazane, N,N′-bis(trimethylsilyl)urea, dimethyltrimethylsilylamine, and trimethylsilyl imidazole; other silanes, such as γ-chloropropyltrimethoxysilane, γ-aminopropyltriethoxysilane, and γ-glycidoxypropyltrimethoxysilane; heterocyclic compounds, such as benzotriazole, benzimidazole, indazole, imidazole, 2-mercaptobenzimidazole, 2-mercaptobenzothiazole, 2-mercaptobenzoxazole, urazole, thiouracil, mercaptoimidazole, mercaptopyrimidine; and urea or thiourea compounds, such as 1,1-dimethylurea and 1,3-dimethylurea.

When such an adhesion aid is used, the amount of the adhesion aid added is ordinarily less than 5 mass %, preferably less than 2 mass %, relative to the total solid content of the silicon-containing resist underlayer film-forming composition.

### <<pH Adjuster>>

In addition, as the pH adjuster, bisphenol S or a bisphenol S derivative may be added, in addition to an acid having one or two or more carboxylic acid groups such as an organic acid described above as <Stabilizer>. The amount of the bisphenol S or the bisphenol S derivative added is 0.01 to 20 parts by mass, 0.01 to 10 parts by mass, or 0.01 to 5 parts by mass relative to 100 parts by mass of the hydrolysis condensate of the hydrolyzable silane mixture.

Hereinafter, specific examples of the bisphenol S and the bisphenol S derivatives will be given, but are not limited thereto.

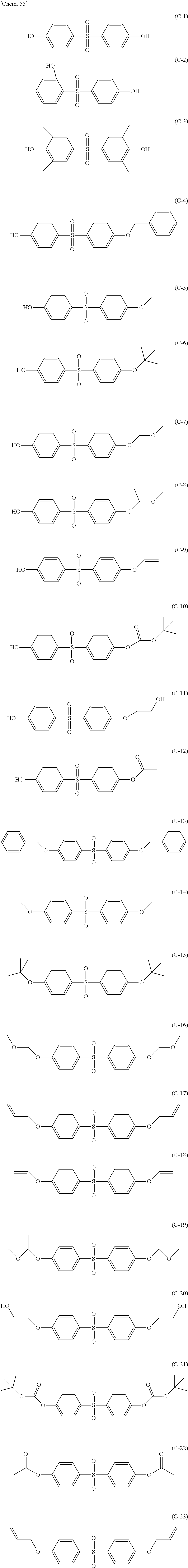

The concentration of the solid component in the silicon-containing resist underlayer film-forming composition may be, for example, 0.1 to 50 mass %, 0.1 to 30 mass %, 0.1 to 25 mass %, or 0.5 to 20.0 mass % relative to the total mass of the composition. The solid component refers to a component resulting from the removal of a solvent component from all the components of the composition.

The content of the hydrolysis condensate of the hydrolyzable silane mixture in the solid component is ordinarily 20 mass % to 100 mass %. From the viewpoint of achieving the above-described effects of the present invention at high reproducibility or the like, the lower limit of the content of the hydrolysis condensate of the hydrolyzable silane mixture is preferably 50 mass %, more preferably 60 mass %, still more preferably 70 mass %, and yet still more preferably 80 mass %. The upper limit of the content is preferably 99 mass %. The balance may be a specific additive (compound A) and other components described below.

Also, the content of the hydrolysis condensate of the hydrolyzable silane mixture in the composition can be, for example, 0.5 to 20.0 mass %.

Further, the silicon-containing resist underlayer film-forming composition preferably has a pH of 2 to 5, more preferably a pH of 3 to 4.

The silicon-containing resist underlayer film-forming composition can be produced by mixing the hydrolysis condensate of the hydrolyzable silane mixture, an organic solvent, and a specific additive (compound A) and other components when the specific additive (compound A) and other components are contained as desired. At this time, a solution containing a hydrolysis condensate or the like may be prepared in advance, and this solution may be mixed with an organic solvent, a specific additive (compound A), and other components.

The order of mixing these components is not particularly limited. For example, the organic solvent may be added to and mixed with the solution containing a hydrolysis condensate or the like, and the specific additive (compound A) and the other components may be added to the mixture, or the solution containing a hydrolysis condensate or the like, the organic solvent, the specific additive (compound A), and the other components may be simultaneously mixed.

If necessary, the organic solvent may be finally added, or some components that can be relatively easily dissolved in the organic solvent may be finally added without being incorporated into the mixture. However, from the viewpoint of preventing aggregation or separation of the components to prepare a highly homogeneous composition with high reproducibility, the composition is preferably produced from a previously prepared solution containing the well-dissolved hydrolysis condensate or the like. Note that attention is paid to the fact that the hydrolysis condensate or the like may aggregate or precipitate when mixed, depending on the type and amount of organic solvent to be mixed together, the amount and properties of other components, and the like. Further, it should be noted that when a composition is prepared from a solution containing the hydrolysis condensate or the like, the concentration of the solution of the hydrolysis condensate or the like or the amount of the solution used must be determined to achieve a desired amount of the hydrolysis condensate or the like contained in the finally produced composition.

During preparation of the composition, the composition may be appropriately heated so long as the components are not decomposed or denatured.

In the present invention, the silicon-containing resist underlayer film-forming composition may be filtered with a submicrometer-order filter or the like during production of the composition or after mixing of all the components. The type of the material of the filter used is not limited. For example, a nylon-made filter or a fluororesin-made filter may be used.

The silicon-containing resist underlayer film-forming composition of the present invention may be suitably used as a composition for forming a silicon-containing resist underlayer film used in a lithography process.

### [Silicon-containing Resist Underlayer Film, Laminate, Method for Forming Pattern, and Method for Producing Semiconductor Element]

The silicon-containing resist underlayer film of the present invention is a cured product of the silicon-containing resist underlayer film-forming composition of the present invention.

The laminate of the present invention includes, for example, a semiconductor substrate and the silicon-containing resist underlayer film of the present invention.

The method for producing a semiconductor element of the present invention includes, for example, the steps of:
forming an organic underlayer film on a substrate;
forming a silicon-containing resist underlayer film on the organic underlayer film using the silicon-containing resist underlayer film-forming composition of the present invention; and
forming a resist film on the silicon-containing resist underlayer film.

The method for forming a pattern of the present invention includes, for example, the steps of:
forming an organic underlayer film on a semiconductor substrate;
applying the silicon-containing resist underlayer film-forming composition of the present invention on the organic underlayer film and baking to form a silicon-containing resist underlayer film;
forming a resist film on the silicon-containing resist underlayer film;
exposing and developing the resist film to obtain a resist pattern;
etching the silicon-containing resist underlayer film using the resist pattern as a mask; and
etching the organic underlayer film using the patterned silicon-containing resist underlayer film as a mask.

Hereinafter, as one aspect of the present invention, a laminate, a method for forming a pattern, and a method for producing a semiconductor element using the silicon-containing resist underlayer film of the present invention or the silicon-containing resist underlayer film-forming composition of the present invention will be described.

First, the silicon-containing resist underlayer film-forming composition of the present invention is applied onto a substrate used for the production of a precise integrated circuit element [e.g. a semiconductor substrate such as a silicon wafer coated with a silicon oxide film, a silicon nitride film, or a silicon oxynitride film, a silicon nitride substrate, a quartz substrate, a glass substrate (including alkali-free glass, low alkali glass, or crystallized glass), a glass substrate coated with an ITO (indium tin oxide) film or an IZO (indium zinc oxide) film, a plastic (e.g. polyimide or PET) substrate, a substrate coated with a low dielectric constant material (low-k material), or a flexible substrate] by an appropriate application method with, for example, a spinner or a coater. Thereafter, the composition is cured through baking by heating means (e.g. a hot plate) to form a silicon-containing resist underlayer film. In the present specification, the term “silicon-containing resist underlayer film” used herein refers to a film formed from the silicon-containing resist underlayer film-forming composition of the present invention.

The baking conditions are appropriately selected from a baking temperature of 40° C. to 400° C., or 80° C. to 250° C., and a baking time of 0.3 minutes to 60 minutes.

Preferably, the baking temperature is 150° C. to 250° C., and the baking time is 0.5 minutes to 2 minutes.

The resist underlayer film formed here has a thickness of, for example, 10 nm to 1,000 nm, or 20 nm to 500 nm, or 50 nm to 300 nm, or 100 nm to 200 nm, or 10 to 150 nm.

In one aspect of the present invention, the organic underlayer film is formed on the substrate, and then the silicon-containing resist underlayer film is formed on the organic underlayer film. In some cases, an aspect may be employed in which the organic underlayer film is not provided.

The organic underlayer film used here is not particularly limited, and may be arbitrarily selected from organic underlayer films commonly used in the lithography process.

In one aspect, the organic underlayer film is formed on the substrate, and the silicon-containing resist underlayer film is formed on the organic underlayer film, followed by formation of a resist film as described below on the silicon-containing resist underlayer film. This can narrow the pattern width of a photoresist film. Thus, even when the photoresist film is formed thinly for preventing pattern collapse, the substrate can be processed through selection of an appropriate etching gas described below. For example, the silicon-containing resist underlayer film can be processed by using, as an etching gas, a fluorine-based gas that achieves a sufficiently high etching rate for the photoresist film. Further, the organic underlayer film can be processed by using, as an etching gas, an oxygen-containing gas that achieves a sufficiently high etching rate for the silicon-containing resist underlayer film. Further, the substrate can be processed by using, as an etching gas, a fluorine-based gas that achieves a sufficiently high etching rate for the organic underlayer film.

The substrate and application method usable in this process include those described above.

Subsequently, for example, a layer (resist film) of a photoresist material is formed on the silicon-containing resist underlayer film. The resist film can be formed by a known method, that is, for example, by applying a coating type resist material (e.g. photoresist film-forming composition) on the resist underlayer film and firing the resist material.

The resist film has a film thickness of, for example, 10 nm to 10,000 nm, or 100 nm to 2,000 nm, or 200 nm to 1,000 nm, or 30 nm to 200 nm.

The photoresist material used for the resist film formed on the silicon-containing resist underlayer film is not particularly limited as long as it is sensitive to light used for exposure (e.g. a KrF excimer laser or an ArF excimer laser), and both a negative photoresist material and a positive photoresist material can be used. Examples of the photoresist include a positive photoresist material formed of a novolac resin and 1,2-naphthoquinone diazide sulfonic acid ester; a chemically amplified photoresist material formed of a binder having a group that is decomposed by an acid to increase an alkali dissolution rate and a photoacid generator; a chemically amplified photoresist material formed of a low molecular weight compound that is decomposed by an acid to increase an alkali dissolution rate of the photoresist material, an alkali-soluble binder, and a photoacid generator; a chemically amplified photoresist material formed of a binder having a group that is decomposed by an acid to increase an alkali dissolution rate, a low molecular weight compound having a group that is decomposed by an acid to increase an alkali dissolution rate of the photoresist material, and photoacid generator.

Specific examples of commercially available products thereof include, but are not limited to, APEX-E (trade name, manufactured by Shipley Company L. L. C), PAR710 (trade name, manufactured by Sumitomo Chemical Co., Ltd.), AR2772JN (trade name, manufactured by JSR Corporation), and SEPR430 (trade name, manufactured by Shin-Etsu Chemical Co., Ltd.). Further, examples of the photoresist include a fluorine-containing polymer-based photoresist material as described in Proc. SPIE, Vol. 3999, 330-334 (2000), Proc. SPIE, Vol. 3999, 357-364 (2000), or Proc. SPIE, Vol. 3999, 365-374 (2000).

As the resist film formed on the silicon-containing resist underlayer film, a resist film for electron beam lithography (also referred to as an electron beam resist film) or a resist film for EUV lithography (also referred to as an EUV resist film) can be used instead of the photoresist film.

As the electron beam resist material for forming the electron beam resist film, both a negative type material and a positive type material can be used. Specific examples of the negative type material and the positive type material include: a chemically amplified resist material containing an acid generator and a binder having a group that is decomposed by an acid to change the alkali dissolution rate; a chemically amplified resist material containing an alkali-soluble binder, an acid generator, and a low molecular weight compound that is decomposed by an acid to change the alkali dissolution rate of the resist material; a chemically amplified resist material containing an acid generator, a binder having a group that is decomposed by an acid to change the alkali dissolution rate, and a low molecular weight compound that is decomposed by an acid to change the alkali dissolution rate of the resist material; a non-chemically amplified resist material containing a binder having a group that is decomposed by an electron beam to change the alkali dissolution rate; and a non-chemically amplified resist material containing a binder having a moiety that is cleaved by an electron beam to change the alkali dissolution rate. Even when these electron beam resist materials are used, a resist film pattern can be formed similarly to a case in which a photoresist material is used with an electron beam being used as an irradiation source.

As the EUV resist material for forming the EUV resist film, a methacrylate resin-based resist material can be used.

The resist material may be a metal-containing resist.

The metal-containing resist is also called a metal oxide resist (metal oxide resist (MOR)), and typical examples thereof include a tin oxide-based resist.

The material of the metal oxide resist is, for example, a coating composition containing a metal oxo-hydroxo network having an organic ligand through a metal carbon bond and/or a metal carboxylate bond described in JP 2019-113855 A.

In an example of the metal-containing resist, a peroxo ligand is used as a radiation-sensitive stabilizing ligand. Details of the peroxo based metal oxo-hydroxo compounds are described, for example, in paragraph of JP 2019-532489 A: Patent Literature. Examples of the Patent Literature include U.S. Pat. No. 9,176,377 B2, US 2013/0224652 A1, U.S. Pat. No. 9,310,684 B2, US 2016/0116839 A1, and U.S. Ser. No. 15/291,738 A.

Subsequently, light exposure is performed on the resist film formed above the silicon-containing resist underlayer film through a predetermined mask (reticle). The light exposure may be performed using a KrF excimer laser (wavelength: 248 nm), an ArF excimer laser (wavelength: 193 nm), an F2 excimer laser (wavelength: 157 nm), EUV (wavelength: 13.5 nm), electron beams, or the like.

After the light exposure, post exposure bake may be performed as necessary. The post exposure bake is performed under appropriately selected conditions: a heating temperature of 70° C. to 150° C. and a heating time of 0.3 minutes to 10 minutes.

Next, development is performed with a developer (e.g. an alkaline developer). When, for example, a positive photoresist film is used, an exposed portion of the photoresist film is removed, and thus a pattern of the photoresist film is formed.

Examples of the developer (alkaline developer) include alkaline aqueous solutions (alkaline developers) such as: aqueous solutions of alkali metal hydroxides such as potassium hydroxide and sodium hydroxide; aqueous solutions of quaternary ammonium hydroxides such as tetramethylammonium hydroxide, tetraethylammonium hydroxide, and choline; and aqueous amine solutions such as ethanolamine, propylamine, and ethylenediamine.

Furthermore, a surfactant or the like may be added to these developers. Development conditions are appropriately selected from a temperature of 5 to 50° C., and a time of 10 seconds to 600 seconds.

In the present invention, an organic solvent can be used as a developer. Development is performed with a developer (solvent) after light exposure. When, for example, a negative photoresist film is used, an unexposed portion of the photoresist film is removed, and thus a pattern of the photoresist film is formed.

Examples of the developer (organic solvent) include methyl acetate, butyl acetate, ethyl acetate, isopropyl acetate, amyl acetate, isoamyl acetate, ethyl methoxyacetate, ethyl ethoxyacetate, propylene glycol monomethyl ether acetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate. Furthermore, a surfactant or the like may be added to these developers. Development conditions are appropriately selected from a temperature of 5° C. to 50° C., and a time of 10 seconds to 600 seconds.

The resultant patterned photoresist film (upper layer) is used as a protective film to remove the silicon-containing resist underlayer film (intermediate layer). Then, a film including the patterned photoresist film and the patterned silicon-containing resist underlayer film (intermediate layer) is used as a protective film to remove the organic underlayer film (lower layer). Finally, the patterned photoresist film (upper layer), the patterned silicon-containing resist underlayer film (intermediate layer) and the patterned organic underlayer film (lower layer) are used as protective films to process the substrate.

The silicon-containing resist underlayer film (intermediate layer) is removed (patterned) through dry etching by using the patterned resist film (upper layer) as a protective film. The dry etching can be performed using any of gases, such as tetrafluoromethane (CF₄), perfluorocyclobutane (C₄F₈), perfluoropropane (C₃F₈), trifluoromethane, carbon monoxide, argon, oxygen, nitrogen, sulfur hexafluoride, difluoromethane, nitrogen trifluoride, chlorine trifluoride, chlorine, trichloroborane, and dichloroborane.

The dry etching of the silicon-containing resist underlayer film is preferably performed using a halogen-containing gas. The resist film (photoresist film) made of an organic material is basically less likely to be removed by dry etching with a halogen-containing gas. In contrast, the silicon-containing resist underlayer film containing numerous silicon atoms is quickly removed by a halogen-containing gas. Therefore, a decrease in the film thickness of the photoresist film due to dry etching of the resist underlayer film can be suppressed. As a result, the photoresist film can be used in the form of thin film. Therefore, the dry etching of the silicon-containing resist underlayer film is preferably performed with a fluorine-based gas, and examples of the fluorine-based gas include, but are not limited to, tetrafluoromethane (CF₄), perfluorocyclobutane (C₄F₈), perfluoropropane (C₃F₈), trifluoromethane, and difluoromethane (CH₂F₂).

When the organic underlayer film is present between the substrate and the silicon-containing resist underlayer film, a film including the patterned resist film (upper layer) (if remains) and the patterned silicon-containing resist underlayer film (intermediate layer) is used as a protective film to remove (pattern) the organic underlayer film (lower layer). The organic underlayer film (lower layer) is preferably removed (patterned) by dry etching with an oxygen-containing gas (e.g. oxygen gas or oxygen/carbonyl sulfide (COS) mixed gas). This is because the silicon-containing resist underlayer film of the present invention, which contains numerous silicon atoms, is less likely to be removed by dry etching with an oxygen-containing gas.

Finally, the patterned silicon-containing resist underlayer film (intermediate layer) and, if desired, the patterned organic underlayer film (lower layer) are used as protective films to process the (semiconductor) substrate. The (semiconductor) substrate is preferably processed (patterned) by dry etching with a fluorine-based gas. Examples of the fluorine-based gas include tetrafluoromethane (CF₄), perfluorocyclobutane (C₄F₈), perfluoropropane (C₃F₈), trifluoromethane, and difluoromethane (CH₂F₂).

In the present invention, after the step of patterning the organic underlayer film, the patterned silicon-containing resist underlayer film can be removed by a chemical solution. Note that removement of the silicon-containing resist underlayer film by a chemical solution can also be performed after processing of the substrate by the patterned organic underlayer film. In the present invention, by using the silicon-containing resist underlayer film-forming composition containing the hydrolysis condensate (polysiloxane), the solubility can be enhanced under alkaline conditions in the film formed from the condensate. For example, the film exhibits excellent solubility in an alkaline solution (basic chemical solution) such as an aqueous solution containing ammonia and hydrogen peroxide. Therefore, the film exhibits favorable peelability when treated with an alkaline solution, and a semiconductor device with less substrate damage can be manufactured by a silicon-containing resist underlayer film that can be easily removed by a chemical solution even if the mask residue is a silicon-based mask residue such as a silicon-containing resist underlayer film.

Examples of the chemical solution include alkaline solutions such as dilute hydrofluoric acid, buffered hydrofluoric acid (mixed solution of HF and NH₄F), an aqueous solution containing hydrochloric acid and hydrogen peroxide (SC-2 chemical solution), an aqueous solution containing sulfuric acid and hydrogen peroxide (SPM chemical solution), an aqueous solution containing hydrofluoric acid and hydrogen peroxide (FPM chemical solution), and an aqueous solution containing ammonia and hydrogen peroxide (SC-1 chemical solution), and it is preferable to use an alkaline chemical solution (basic chemical solution) from the viewpoint of reducing the influence on the substrate.

Further, examples of the alkaline solution include an aqueous solution containing 1 to 99 mass % of ammonia, tetramethylammonium hydroxide, tetraethylammonium hydroxide, tetrapropylammonium hydroxide, tetrabutylammonium hydroxide, choline hydroxide, benzyltrimethylammonium hydroxide, benzyltriethylammonium hydroxide, DBU (diazabicycloundecene), DBN (diazabicyclononene), hydroxylamine, 1-butyl-1-methylpyrrolidinium hydroxide, 1-propyl-1-methylpyrrolidinium hydroxide, 1-butyl-1-methylpiperidinium hydroxide, 1-propyl-1-methylpiperidinium hydroxide, mepiquat hydroxide, trimethylsulfonium hydroxide, a hydrazine compound, an ethylenediamine compound, or guanidine, in addition to the ammonia-hydrogen peroxide mixture prepared by mixing ammonia, hydrogen peroxide solution, and water described above (SC-1 chemical solution).

An organic antireflection film may be formed on the silicon-containing resist underlayer film before formation of the resist film. The antireflection film composition to be used is not particularly limited, and can be arbitrarily selected and used, for example, from those conventionally used in a lithography process, and the antireflection film can be formed by a commonly used method, for example, coating using a spinner or a coater and firing.

In addition, the substrate to which the silicon-containing resist underlayer film-forming composition of the present invention is applied may have an organic or inorganic antireflection film formed by a CVD method or the like on the surface thereof, and the resist underlayer film can be formed thereon. When the organic underlayer film is formed on the substrate and then the resist underlayer film of the present invention is formed thereon, the substrate to be used may have an organic or inorganic antireflection film formed by a CVD method or the like on the surface thereof.

The silicon-containing resist underlayer film formed from the silicon-containing resist underlayer film-forming composition of the present invention may absorb light used in a lithography process depending on the wavelength of the light. In such a case, the resist underlayer film can function as an antireflection film having the effect of preventing reflection of light from the substrate.

Furthermore, the silicon-containing resist underlayer film can be used as, for example, a layer for preventing the interaction between the substrate and the resist film (such as a photoresist film); a layer having the function of preventing the adverse effect, on the substrate, of a material used for the resist film or a substance generated during the exposure of the resist film to light; a layer having the function of preventing diffusion of a substance generated from the substrate during heating and baking to the resist film; and a barrier layer for reducing a poisoning effect of a dielectric layer of the semiconductor substrate on the resist film.

The silicon-containing resist underlayer film can be applied to a substrate having via holes for use in a dual damascene process, and can be used as a hole filling material (embedding material) to fill up the holes. The silicon-containing resist underlayer film can also be used as a planarization material for planarizing the surface of a semiconductor substrate having irregularities.

As an underlayer of EUV resist film, the silicon-containing resist underlayer film also can be used as a lower layer antireflection film of EUV resist film capable of, without intermixing with the EUV resist film, preventing the reflection, from a substrate or an interface, of exposure light undesirable for EUV exposure (wavelength: 13.5 nm), such as UV (ultraviolet) light or DUV (deep ultraviolet) light (ArF light, KrF light), in addition to the function as a hard mask. Thus, the silicon-containing resist underlayer film can efficiently prevent the light reflection as the underlayer film of the EUV resist film. When the silicon-containing resist underlayer film is used as an EUV resist underlayer film, the film can be processed in a similar manner to the photoresist underlayer film.

A semiconductor substrate can be suitably processed by using a laminate including the above-described silicon-containing resist underlayer film of the present invention and a semiconductor substrate.

In addition, a semiconductor substrate can be precisely processed at high reproducibility by the above-described semiconductor element production method including the steps of: forming an organic underlayer film; forming a silicon-containing resist underlayer film on the organic underlayer film using the silicon-containing resist underlayer film-forming composition of the present invention; and forming a resist film on the silicon-containing resist underlayer film. Thus, it is expected that the method can stably produce a semiconductor element.

### EXAMPLES

Hereinafter, the contents and effects of the present invention will be described in more detail by way of examples, but the present invention is not limited thereto.

As a hydrolysis condensate of a hydrolyzable silane (polyorganosiloxane), a condensate having a weight-average molecular weight of 1,000 to 1 million or 1,000 to 100,000 can be obtained. The molecular weight is a molecular weight obtained in terms of polystyrene by GPC analysis.

The GPC analysis can be performed, for example, under the following conditions: GPC apparatus (trade name: HLC-8220GPC, manufactured by Tosoh Corporation), GPC columns (trade name: Shodex (registered trademark) KF803L, KF802, and KF801, manufactured by Showa Denko K.K.), column temperature of 40° C., tetrahydrofuran as an eluent (elution solvent), flow amount (flow rate) of 1.0 mL/min, and polystyrene (manufactured by Showa Denko K.K.) as a standard sample.

[1] Synthesis Examples 1 to 7 and Comparative Synthesis Example 1: Synthesis of Hydrolysis Condensates (Polysiloxanes) was Performed. Compounds 1 to 6 Used in Each Synthesis are Shown Below.

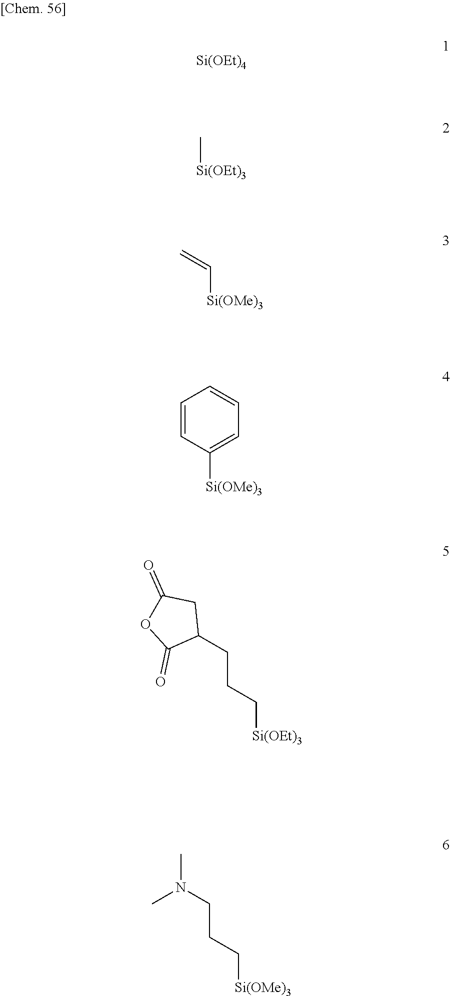

In the formulae, Me represents a methyl group, and Et represents an ethyl group.

### Synthesis Example 1

In a 100-mL flask, 13.52 g of the compound 1, 2.82 g of the compound 3, 2.97 g of the compound 4, 0.21 g of the compound 5, 0.03 g of the compound 6, and 30 g of 1-ethoxy-2-propanol (propylene glycol monoethyl ether) were charged and stirred, and 12.6 g of a 0.2 mol/L aqueous nitric acid solution was added dropwise thereto while stirring the resulting solution with a magnetic stirrer.

After the dropwise addition, the flask was transferred to an oil bath set at 65° C. and the mixed solution was reacted for 20 hours. Thereafter, the reaction solution was cooled to room temperature, 40 g of 1-ethoxy-2-propanol was added to the reaction solution, and water and nitric acid, and methanol and ethanol as reaction by-products were distilled off under reduced pressure to obtain a concentrated solution of a hydrolysis condensate (polymer) using 1-ethoxy-2-propanol as a solvent. The solid content concentration of the obtained concentrated solution was more than 20 mass % in terms of solid residue when heated at 150° C.

The weight-average molecular weight (Mw) of the obtained hydrolysis condensate (polysiloxane) as measured by GPC was 2,000 in terms of polystyrene.

<Synthesis Example 2> to <Synthesis Example 7> were performed using compounds (monomers) shown in Table 1 under the same conditions as in Synthesis Example 1 to obtain hydrolysis condensates (polysiloxane compounds) 2 to 7 as target substances.

TABLE 1

| | | | | | | | | Weight- |
|---|---|---|---|---|---|---|---|---|
| | | | | | | | | average |
| | | Compound | Compound | Compound | Compound | Compound | Compound | molecular |
| | | 1 | 2 | 3 | 4 | 5 | 6 | weight |
| Synthesis | g | 13.52 | — | 2.82 | 2.97 | 0.21 | 0.03 | 2000 |
| Example 1 | Mol % | 64.9 | — | 19.0 | 15.0 | 1.0 | 0.1 | |
| Synthesis | g | 15.62 | — | 0.44 | 3.97 | 0.21 | 0.30 | 2100 |
| Example 2 | Mol % | 75.0 | — | 3.0 | 20.0 | 1.0 | 1.0 | |
| Synthesis | g | 15.62 | — | — | 4.56 | 0.21 | 0.30 | 1900 |
| Example 3 | Mol % | 75.0 | — | — | 23.0 | 1.0 | 1.0 | |
| Synthesis | g | 15.62 | — | 1.30 | 2.97 | 0.21 | 0.08 | 2300 |
| Example 4 | Mol % | 75.0 | — | 8.8 | 15.0 | 1.0 | 0.3 | |
| Synthesis | g | 15.62 | — | 1.26 | 2.97 | 0.21 | 0.15 | 2200 |
| Example 5 | Mol % | 75.0 | — | 8.5 | 15.0 | 1.0 | 0.5 | |
| Synthesis | g | 15.62 | — | 1.22 | 2.97 | 0.21 | 0.23 | 2300 |
| Example 6 | Mol % | 75.0 | — | 8.3 | 15.0 | 1.0 | 0.8 | |
| Synthesis | g | 15.62 | — | 1.19 | 2.97 | 0.21 | 0.30 | 2300 |
| Example 7 | Mol % | 75.0 | — | 8.0 | 15.0 | 1.0 | 1.0 | |

### Comparative Synthesis Example 1

In a 100-mL flask, 14.58 g of the compound 1, 5.35 g of the compound 2, and 30 g of 1-ethoxy-2-propanol were charged and stirred, and 12.6 g of a 0.2 mol/L aqueous nitric acid solution was added dropwise thereto while stirring the resulting solution with a magnetic stirrer.

After the dropwise addition, the flask was transferred to an oil bath set at 65° C. and the mixed solution was reacted for 20 hours. Thereafter, the reaction solution was cooled to room temperature, 40 g of 1-ethoxy-2-propanol was added to the reaction solution, and water and nitric acid, and methanol and ethanol as reaction by-products were distilled off under reduced pressure to obtain a concentrated solution of a hydrolysis condensate (polymer) using 1-ethoxy-2-propanol as a solvent. The solid content concentration of the obtained concentrated solution was more than 20 mass % in terms of solid residue when heated at 150° C.

The weight-average molecular weight (Mw) of the obtained hydrolysis condensate (polysiloxane) as measured by GPC was 3, 200 in terms of polystyrene.

### [2] Preparation Examples 1 to 20 and Comparative Preparation Example 1: Preparation of Silicon-Containing Resist Underlayer Film-Forming Compositions (Application Liquids)

Additives and solvents were mixed with the hydrolysis condensates (polymers) 1 to 7 obtained in the Synthesis Examples and the hydrolysis condensate (polymer) of Comparative Synthesis Example 1 in the proportions shown in Table 2-1 or Table 2-2, and the mixture was filtered through a 0.02 μm polyethylene filter to prepare each polysiloxane underlayer film-forming composition solution. In Tables 2-1 and 2-2, the amount of each component added is shown by part(s) by mass.

In Tables 2-1 and 2-2, 0.9 parts by mass described in the column of composition of each synthesis example means that the amount of the hydrolysis condensate is 0.9 parts by mass. Also, in Tables 2-1 and 2-2, PGEE means propylene glycol monoethyl ether, PGME means propylene glycol monomethyl ether, and DIW means ultrapure water.

Further, in Tables 2-1 and 2-2, A, B, and C₁ to C₃ are additives represented by the following structural formulae, respectively.

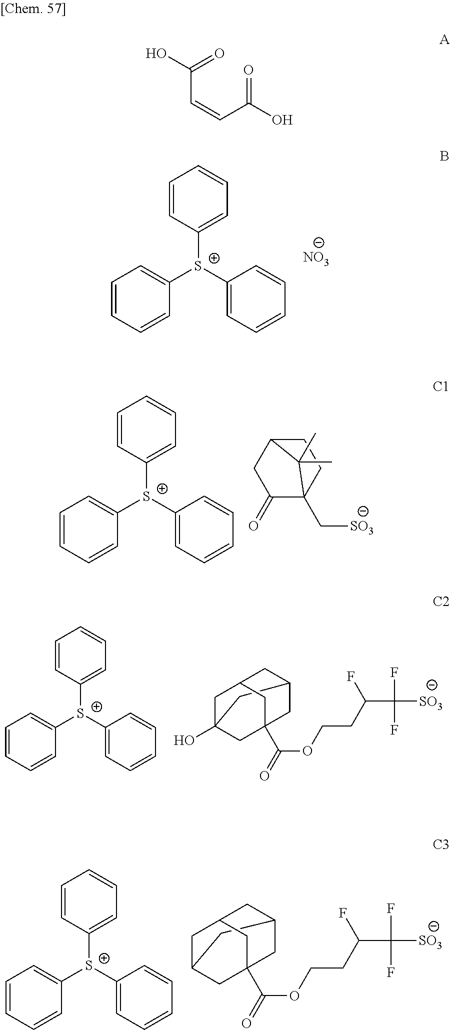

### <Measurement of Cap Ratio>

The cap ratio based on 1-ethoxy-2-propanol was calculated by ¹HNMR. The measurement was performed using JNM-ECA500 (manufactured by JEOL Ltd.). First, an integral ratio of a chemical shift value (7.0 to 8.0 ppm) of protons of trimethoxyphenylsilane was taken as a reference. The chemical shift value of the α-position methine proton of 1-ethoxy-2-propanol is detected around 3.8 ppm, but when a bond is formed with a silicon atom by a dehydration condensation reaction with a silanol group, that is, when a cap reaction occurs with respect to the silanol group, the chemical shift value of the methine proton moves to around 4.2 ppm. The integral ratio of the methine protons having moved to around 4.2 ppm was measured, and the cap ratio based on 1-ethoxy-2-propanol was calculated using Formula (Cap) described above by comparing with the integral ratio of the proton measured previously.

In Comparative Preparation Example 1, the proton of the methyl group of triethoxymethylsilane was used as a reference proton. The chemical shift value is 0.0 to 0.3 ppm.

TABLE 2-1

| | | | | | | | | | | Cap |
|---|---|---|---|---|---|---|---|---|---|---|
| | | | Additive | | | | Solvent | | | ratio |
| | | Polymer | 1 | 2 | 3 | 4 | 1 | 2 | 3 | (%) |
| Preparation | Component | Synthesis | A | B | — | — | PGEE | PGME | — | 4 |
| Example 1 | | Example 1 | | | | | | | | |
| | (parts by | 0.9 | 0.009 | 0.005 | | | 92 | 8 | | |
| | mass) | | | | | | | | | |
| Preparation | Component | Synthesis | A | B | C1 | — | PGEE | PGME | — | 4 |
| Example 2 | | Example 1 | | | | | | | | |
| | (parts by | 0.9 | 0.009 | 0.005 | 0.07 | | 92 | 8 | | |
| | mass) | | | | | | | | | |
| Preparation | Component | Synthesis | A | B | C1 | — | PGEE | PGME | — | — |
| Example 3 | | Example 2 | | | | | | | | |
| | (parts by | 0.9 | 0.009 | 0.005 | 0.07 | | 92 | 8 | | |
| | mass) | | | | | | | | | |
| Preparation | Component | Synthesis | A | B | C1 | — | PGEE | PGME | — | — |
| Example 4 | | Example 3 | | | | | | | | |
| | (parts by | 0.9 | 0.009 | 0.005 | 0.07 | | 92 | 8 | | |
| | mass) | | | | | | | | | |
| Preparation | Component | Synthesis | A | B | C1 | — | PGEE | PGME | — | — |
| Example 5 | | Example 4 | | | | | | | | |
| | (parts by | 0.9 | 0.009 | 0.005 | 0.07 | | 92 | 8 | | |
| | mass) | | | | | | | | | |
| Preparation | Component | Synthesis | A | B | C1 | — | PGEE | PGME | — | — |
| Example 6 | | Example 5 | | | | | | | | |
| | (parts by | 0.9 | 0.009 | 0.005 | 0.07 | | 92 | 8 | | |
| | mass) | | | | | | | | | |
| Preparation | Component | Synthesis | A | B | C1 | — | PGEE | PGME | — | — |
| Example 7 | | Example 6 | | | | | | | | |
| | (parts by | 0.9 | 0.009 | 0.005 | 0.07 | | 92 | 8 | | |
| | mass) | | | | | | | | | |
| Preparation | Component | Synthesis | A | B | C1 | — | PGEE | PGME | — | 8 |
| Example 8 | | Example 7 | | | | | | | | |
| | (parts by | 0.9 | 0.009 | 0.005 | 0.07 | | 92 | 8 | | |
| | mass) | | | | | | | | | |
| Preparation | Component | Synthesis | A | B | — | — | PGEE | PGME | — | 8 |
| Example 9 | | Example 7 | | | | | | | | |
| | (parts by | 0.9 | 0.009 | 0.005 | | | 92 | 8 | | |
| | mass) | | | | | | | | | |
| Preparation | Component | Synthesis | A | B | C1 | — | PGEE | PGME | — | 8 |
| Example 10 | | Example 7 | | | | | | | | |
| | (parts by | 0.9 | 0.009 | 0.005 | 0.02 | | 92 | 8 | | |
| | mass) | | | | | | | | | |
| Preparation | Component | Synthesis | A | B | C1 | — | PGEE | PGME | — | 8 |
| Example 11 | | Example 7 | | | | | | | | |
| | (parts by | 0.9 | 0.009 | 0.005 | 0.03 | | 92 | 8 | | |
| | mass) | | | | | | | | | |

TABLE 2-2

| | | | Additive | | | | Solvent | | | Cap |
|---|---|---|---|---|---|---|---|---|---|---|
| | | Polymer | 1 | 2 | 3 | 4 | 1 | 2 | 3 | ratio |
| Preparation | Component | Synthesis | A | B | C1 | — | PGEE | PGME | — | 8 |
| Example 12 | | Example 7 | | | | | | | | |
| | (parts by | 0.9 | 0.009 | 0.005 | 0.05 | | 92 | 8 | | |
| | mass ) | | | | | | | | | |
| Preparation | Component | Synthesis | A | B | C1 | — | PGEE | PGME | — | 8 |
| Example 13 | | Example 7 | | | | | | | | |
| | (parts by | 0.9 | 0.009 | 0.005 | 0.09 | | 92 | 8 | | |
| | mass) | | | | | | | | | |
| Preparation | Component | Synthesis | A | — | C1 | — | PGEE | PGME | — | 8 |
| Example 14 | | Example 7 | | | | | | | | |
| | (parts by | 0.9 | 0.009 | | 0.07 | | 92 | 8 | | |
| | mass) | | | | | | | | | |
| Preparation | Component | Synthesis | A | B | C2 | — | PGEE | PGME | — | 8 |
| Example 15 | | Example 7 | | | | | | | | |
| | (parts by | 0.9 | 0.009 | 0.005 | 0.02 | | 92 | 8 | | |
| | mass) | | | | | | | | | |
| Preparation | Component | Synthesis | A | B | C2 | — | PGEE | PGME | — | 8 |
| Example 16 | | Example 7 | | | | | | | | |
| | (parts by | 0.9 | 0.009 | 0.005 | 0.03 | | 92 | 8 | | |
| | mass) | | | | | | | | | |
| Preparation | Component | Synthesis | A | B | C3 | — | PGEE | PGME | — | 8 |
| Example 17 | | Example 7 | | | | | | | | |
| | (parts by | 0.9 | 0.009 | 0.005 | 0.02 | | 92 | 8 | | |
| | mass) | | | | | | | | | |
| Preparation | Component | Synthesis | A | B | C3 | — | PGEE | PGME | — | 8 |
| Example 18 | | Example 7 | | | | | | | | |
| | (parts by | 0.9 | 0.009 | 0.005 | 0.03 | | 92 | 8 | | |
| | mass) | | | | | | | | | |
| Preparation | Component | Synthesis | A | B | C1 | C3 | PGEE | PGME | — | 8 |
| Example 19 | | Example 7 | | | | | | | | |
| | (parts by | 0.9 | 0.009 | 0.005 | 0.05 | 0.02 | 92 | 8 | | |
| | mass) | | | | | | | | | |
| Preparation | Component | Synthesis | A | B | C1 | C3 | PGEE | PGME | — | 8 |
| Example 20 | | Example 7 | | | | | | | | |
| | (parts by | 0.9 | 0.009 | 0.005 | 0.03 | 0.03 | 92 | 8 | | |
| | mass) | | | | | | | | | |
| Comparative | Component | Comparative | A | B | — | — | PGEE | PGME | DIW | 0 |
| Preparation | | Synthesis | | | | | | | | |
| Example 1 | | Example 1 | | | | | | | | |
| | (parts by | 0.9 | 0.009 | 0.003 | | | 80 | 8 | 12 | |
| | mass) | | | | | | | | | |

### [3] Preparation of Organic Underlayer Film-Forming Composition

In a nitrogen atmosphere, a 100-mL four-necked flask was charged with 6.69 g (0.040 mol) of carbazole (manufactured by Tokyo Chemical Industry Co., Ltd.), 7.28 g (0.040 mol) of 9-fluorenone (manufactured by Tokyo Chemical Industry Co., Ltd.), and 0.76 g (0.0040 mol) of p-toluenesulfonic acid monohydrate (manufactured by Tokyo Chemical Industry Co., Ltd.), and then 6.69 g of 1,4-dioxane (manufactured by Kanto Chemical Co., Inc.) was added thereto. The resultant mixture was stirred and then heated to 100° C. to dissolve the solid, and thus polymerization was initiated.

After 24 hours, the reaction mixture was allowed to cool to 60° C., and diluted with 34 g of chloroform (manufactured by Kanto Chemical Co., Inc.), and the diluted reaction mixture was added dropwise to 168 g of methanol (manufactured by Kanto Chemical Co., Inc.) for reprecipitation. The resultant precipitate was subjected to filtration and recovery, and the recovered solid was dried at 80° C. for 24 hours to obtain 9.37 g of a desired polymer represented by Formula (X) (hereinafter, abbreviated as PCzFL).

The results of ¹H-NMR measurement of PCzFL were as follows.

¹H-NMR (400 MHz, DMSO-d₆): δ7.03-7.55 (br, 12H), δ7.61-8.10 (br, 4H), δ11.18 (br, 1H)

Further, PCzFL was found to have a weight-average molecular weight (Mw) of 2,800 as determined by GPC in terms of polystyrene and a polydispersity Mw/Mn of 1.77.

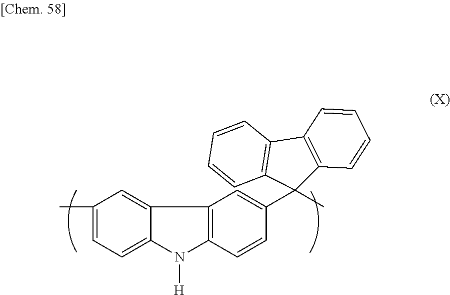

20 g of PCzFL was mixed with 3.0 g of tetramethoxymethyl glycoluril (trade name: Powderlink 1174, manufactured by Cytec Industries Japan (former Mitsui Cytec Ltd.)) serving as a crosslinking agent, 0.30 g of pyridinium para-toluenesulfonate serving as a catalyst, and 0.06 g of MEGAFACE R-30 (trade name, manufactured by DIC Corporation) serving as a surfactant, and the mixture was dissolved in 88 g of propylene glycol monomethyl ether acetate to prepare a solution. Thereafter, the solution was filtered using a polyethylene microfilter having a pore size of 0.10 μm, and further filtered using a polyethylene microfilter having a pore size of 0.05 μm to prepare an organic underlayer film-forming composition.

### [4] Evaluation of Resist Patterning by ArF Exposure

The organic underlayer film-forming composition was applied onto a silicon wafer using a spinner, and heated on a hot plate at 240° C. for 60 seconds to form an organic underlayer film (A layer) (film thickness: 200 nm).

The application liquid obtained in Preparation Example 1 was spin-coated on the organic underlayer film, and then heated on a hot plate at 215° C. for 1 minute to form a silicon-containing resist underlayer film (B layer (20 nm)).

Further, a commercially available ArF resist (manufactured by JSR Corporation, trade name: AR2772JN) was spin-coated thereon, and heated on a hot plate at 110° C. for 90 seconds to form a resist film (C layer) (120 nm). Thereafter, a scanner: NSR-S307E, manufactured by Nikon Corporation (wavelength: 193 nm, NA: 0.85, σ: 0.85/0.93) was used to expose the films through a mask designed such that the line width and the width between the lines of the photoresist after the following development were 0.065 μm, i.e. a 0.065 μm dense line with a line and space (L/S)=1/1 was formed.

After the light exposure, post exposure bake (110° C., for 1 minute) was performed, and then the resist layer was cooled on a cooling plate to room temperature, followed by development with a 2.38% aqueous alkali solution for 60 seconds and rinsing treatment to form a resist pattern. In the same procedure, resist patterns were formed using each of the application liquids obtained in Preparation Examples 2 to 20 and Comparative Preparation Example 1.

The experimental results using Preparation Examples 1 to 20 were designated as Examples 1 to 20, and the experimental result using Comparative Preparation Example 1 was designated as Comparative Example 1.

Each of the thus-formed photoresist patterns was evaluated by determining the pattern shape through observation of a cross section of the pattern. Evaluation “Good” was given when pattern collapse (significant pattern peeling, undercut, or a wide-bottomed line (footing)) did not occur, and evaluation “Poor” was given when pattern collapse occurred. The obtained results are shown in Table 3.

[5] Evaluation of Removability with Alkaline Chemical Solution

The application liquid obtained in Preparation Example 1 was spin-coated on a silicon wafer, and then heated on a hot plate at 215° C. for 1 minute to form a silicon-containing resist underlayer film (B layer (20 nm)).

In the same procedure, silicon-containing resist underlayer films were formed using each of the application liquids obtained in Preparation Examples 2 to 20 and Comparative Preparation Example 1.

The silicon wafer having the thus-formed silicon-containing resist underlayer film was immersed in an alkaline chemical solution (manufactured by Tokyo Ohka Kogyo Co., Ltd.) adjusted to a liquid temperature of 30° C. for 180 seconds, then the silicon wafer was rinsed with water for 60 seconds, followed by drying. The thickness of the silicon-containing resist underlayer film after immersion was measured, and the rate of change (%) in film thickness was calculated. Evaluation “Very Good” was given when the rate of change in the film thickness of the silicon-containing resist underlayer film after the immersion with respect to the film thickness before the immersion was 90% or more, evaluation “Good” was given when the rate of change in film thickness was 80% or more and less than 90%, and evaluation “Poor” was given when the rate of change was less than 80%. The obtained results are shown in Table 3. The rate of change is obtained by the following equation.

$$Rate of change ( \% ) = [ 1 - ( A / B ) ] \times 100$$

A: Film thickness of silicon-containing resist underlayer film after immersion
B: Film thickness of silicon-containing resist underlayer film before immersion
   [6] Evaluation of Removability with SC-1 Chemical Solution (Ammonia/Hydrogen Peroxide Aqueous Solution)

The application liquid obtained in Preparation Example 1 was spin-coated on a silicon wafer, and then heated on a hot plate at 215° C. for 1 minute to form a silicon-containing resist underlayer film (B layer (20 nm)).

In the same procedure, silicon-containing resist underlayer films were formed using each of the application liquids obtained in Preparation Examples 2 to 20 and Comparative Preparation Example 1.

The silicon wafer having the thus-formed silicon-containing resist underlayer film was immersed in SC-1 chemical solution (28% aqueous ammonia/33% hydrogen peroxide solution/water=1/1/10 (v/v/v)) adjusted to a liquid temperature of 60° C. for 180 seconds, then the silicon wafer was rinsed with water for 60 seconds, followed by drying. Then, the thickness of the silicon-containing resist underlayer film after immersion in the SC-1 chemical solution was measured, and the rate of change (%) in film thickness was calculated. Evaluation “Good” was given when the rate of change in the film thickness of the silicon-containing resist underlayer film after the immersion with respect to the film thickness before the immersion was 15% or more, and evaluation “Poor” was given when the rate of change was less than 15%. The obtained results are shown in Table 3. The rate of change is obtained by the following equation.

$$Rate of change ( \% ) = [ 1 - ( A / B ) ] \times 100$$

A: Film thickness of silicon-containing resist underlayer film after immersion
B: Film thickness of silicon-containing resist underlayer film before immersion

TABLE 3

| | | | Removability | Removability |
|---|---|---|---|---|
| | | Pattern | with alkaline | with SC-1 |
| | | shape | chemical | chemical |
| Example 1 | Preparation | Good | Good | Good |
| | Example 1 | | | |
| Example 2 | Preparation | Good | Good | Good |
| | Example 2 | | | |
| Example 3 | Preparation | Good | Good | Good |
| | Example 3 | | | |
| Example 4 | Preparation | Good | Good | Good |
| | Example 4 | | | |
| Example 5 | Preparation | Good | Good | Good |
| | Example 5 | | | |
| Example 6 | Preparation | Good | Good | Good |
| | Example 6 | | | |
| Example 7 | Preparation | Good | Good | Good |
| | Example 7 | | | |
| Example 8 | Preparation | Good | Good | Good |
| | Example 8 | | | |
| Example 9 | Preparation | Good | Good | Good |
| | Example 9 | | | |
| Example 10 | Preparation | Good | Good | Good |
| | Example 10 | | | |
| Example 11 | Preparation | Good | Good | Good |
| | Example 11 | | | |
| Example 12 | Preparation | Good | Good | Good |
| | Example 12 | | | |
| Example 13 | Preparation | Good | Good | Good |
| | Example 13 | | | |
| Example 14 | Preparation | Good | Good | Good |
| | Example 14 | | | |
| Example 15 | Preparation | Good | Good | Good |
| | Example 15 | | | |
| Example 16 | Preparation | Good | Good | Good |
| | Example 16 | | | |
| Example 17 | Preparation | Good | Good | Good |
| | Example 17 | | | |
| Example 18 | Preparation | Good | Good | Good |
| | Example 18 | | | |
| Example 19 | Preparation | Good | Good | Good |
| | Example 19 | | | |
| Example 20 | Preparation | Good | Good | Good |
| | Example 20 | | | |
| Comparative | Comparative | — | Poor | Poor |
| Example 1 | Preparation | | | |
| | Example 1 | | | |

1. A silicon-containing resist underlayer film-forming composition comprising a hydrolysis condensate of a hydrolyzable silane mixture and an organic solvent, wherein
at least a part of silanol groups in the hydrolysis condensate is capped with an alcohol-based compound,
which is a composition for forming a silicon-containing resist underlayer film soluble in a basic chemical solution.

2. The silicon-containing resist underlayer film-forming composition according to claim 1, wherein a cap ratio based on the alcohol-based compound in the hydrolysis condensate is 4% to 9%.

3. The silicon-containing resist underlayer film-forming composition according to claim 1, wherein the alcohol-based compound is an alkylene glycol monoalkyl ether.

4. The silicon-containing resist underlayer film-forming composition according to claim 1, wherein the composition does not substantially contain water.

5. The silicon-containing resist underlayer film-forming composition according to claim 1, wherein the hydrolyzable silane mixture contains a hydrolyzable silane represented by the following Formula (1): 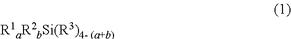
wherein,
R¹ is a group bonded to a silicon atom, and represents an organic group containing a succinic anhydride skeleton,
R² is a group bonded to a silicon atom, and each independently represents an optionally substituted alkyl group, an optionally substituted halogenated alkyl group, or an optionally substituted alkoxyalkyl group, or represents an organic group containing an epoxy group, an acryloyl group, a methacryloyl group, a mercapto group, an amino group, an amide group, an alkoxy group, a sulfonyl group, or a cyano group, or a combination thereof,
R³ is a group or atom bonded to a silicon atom, and each independently represents an alkoxy group, an aralkyloxy group, an acyloxy group, or a halogen atom,
a represents 1, b represents an integer of 0 to 2, and 4−(a+b) represents an integer of 1 to 3.

6. The silicon-containing resist underlayer film-forming composition according to claim 1, wherein the hydrolyzable silane mixture contains a hydrolyzable silane represented by the following Formula (2): 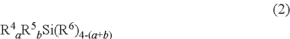
wherein,
R⁴ is a group bonded to a silicon atom, and represents an organic group containing an optionally substituted amino group,
R⁵ is a group bonded to a silicon atom, and each independently represents an optionally substituted alkyl group, an optionally substituted halogenated alkyl group, or an optionally substituted alkoxyalkyl group, or represents an organic group containing an epoxy group, an acryloyl group, a methacryloyl group, a mercapto group, an amino group, an amide group, an alkoxy group, a sulfonyl group, or a cyano group, or a combination thereof,
R⁶ is a group or atom bonded to a silicon atom, and each independently represents an alkoxy group, an aralkyloxy group, an acyloxy group, or a halogen atom,
a represents 1, b represents an integer of 0 to 2, and 4−(a+b) represents an integer of 1 to 3.

7. The silicon-containing resist underlayer film-forming composition according to claim 1, wherein the hydrolyzable silane mixture contains a hydrolyzable silane represented by the following Formula (4): 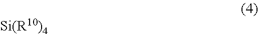
wherein
R¹⁰ is a group or atom bonded to a silicon atom, and each independently represents an alkoxy group, an aralkyloxy group, an acyloxy group, or a halogen atom.

8. The silicon-containing resist underlayer film-forming composition according to claim 7, wherein a molar ratio of the hydrolyzable silane represented by Formula (4) in the hydrolyzable silane mixture is 50 mol % or more.

9. The silicon-containing resist underlayer film-forming composition according to claim 1, further comprising a compound A having a chemical structure containing a cation AX⁺ and an anion AZ⁻, wherein the anion has a molecular weight of 65 or more.

10. The silicon-containing resist underlayer film-forming composition according to claim 9, wherein the anion AZ⁻ is at least one anion selected from the group consisting of anions represented by the following (A) to (E): 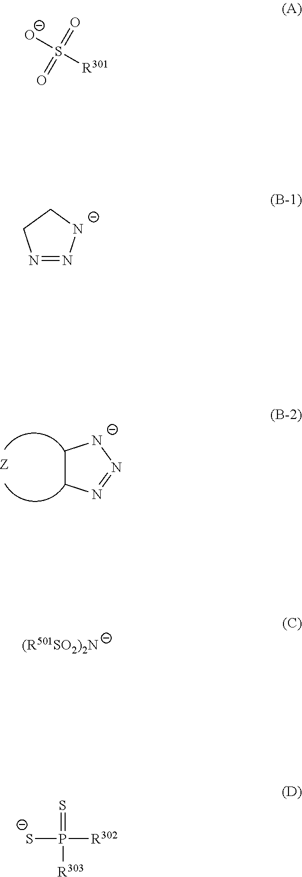
wherein in Formulae (A) to (E),
R³⁰¹ represents an optionally substituted alkyl group, an optionally substituted aryl group, an optionally substituted halogenated alkyl group, an optionally substituted aralkyl group, or an organic group containing an ester bond (—C(═O)—O— or —O—C(═O)—), or a combination thereof,
Z represents an aromatic ring, a cyclic alkane, or a cyclic alkene of a non-aromatic ring,
R⁵⁰¹ represents an alkyl group in which some or all may be substituted with a fluorine atom,
R³⁰² and R³⁰³ each independently represent an alkyl group, and
R³⁰⁴ and R³⁰⁵ each independently represent an alkyl group.

11. The silicon-containing resist underlayer film-forming composition according to claim 1, wherein the hydrolyzable silane mixture contains a hydrolyzable silane represented by the following Formula (3): 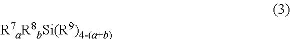
wherein,
R⁷ is a group bonded to a silicon atom, and represents an organic group containing an alkenyl group,
R⁸ is a group bonded to a silicon atom, and each independently represents an optionally substituted alkyl group, an optionally substituted halogenated alkyl group, or an optionally substituted alkoxyalkyl group, or represents an organic group containing an epoxy group, an acryloyl group, a methacryloyl group, a mercapto group, an amino group, an amide group, an alkoxy group, a sulfonyl group, or a cyano group, or a combination thereof,
R⁹ is a group or atom bonded to a silicon atom, and each independently represents an alkoxy group, an aralkyloxy group, an acyloxy group, or a halogen atom,
a represents 1, b represents an integer of 0 to 2, and 4−(a+b) represents an integer of 1 to 3.

12. A silicon-containing resist underlayer film formed by using the resist underlayer film-forming composition according to claim 1.

13. A method for forming a pattern,
comprising steps of:
forming an organic underlayer film on a semiconductor substrate;
applying the resist underlayer film-forming composition according to claim 1 on the organic underlayer film and baking to form a silicon-containing resist underlayer film;
forming a resist film on the silicon-containing resist underlayer film;
exposing and developing the resist film to obtain a resist pattern;
etching the silicon-containing resist underlayer film using the resist pattern as a mask; and
etching the organic underlayer film using the patterned silicon-containing resist underlayer film as a mask.

14. The method for forming a pattern according to claim 13,
further comprising a step of removing the silicon-containing resist underlayer film by a wet method using a chemical solution, after the step of etching the organic underlayer film.

15. The method for forming a pattern according to claim 14, wherein the chemical solution is a basic chemical solution.
